(19) United States
(12) Patent Application Publication
(10) Pub. No.: US 2025/0007364 A1
(43) Pub. Date: Jan. 2, 2025

(54) HIGH VOLTAGE ELECTRIC FAN SYSTEM

(71) Applicant: HORTON, INC., Roseville, MN (US)

(72) Inventors: Tristan Carlson, Woodbury, MN (US); Meng Yang, Blaine, MN (US); Nicholas Heymer, Crystal, MN (US); Michael Stevens, Roseville, MN (US); Andrew Strong, Woodbury, MN (US); Timothy Grotheer, Roseville, MN (US); Jonathan Ackermann, Circle Pines, MN (US); Derek Savela, St. Paul, MN (US); Brett Bauman, Minneapolis, MN (US)

(21) Appl. No.: 18/829,558

(22) Filed: Sep. 10, 2024

Related U.S. Application Data
(62) Division of application No. PCT/US2023/064617, filed on Mar. 17, 2023.
(60) Provisional application No. 63/269,575, filed on Mar. 18, 2022.

(51) Int. Cl. H02K 11/33; H02K 5/04; H02K 7/14; H05K 7/20

(52) U.S. Cl. CPC H02K 11/33; H02K 5/04; H02K 7/14; H05K 7/20927

(57) ABSTRACT

An electric cooling fan system can include a frame, a first fan, a first electric motor assembly supported by the frame and operably connected to the first fan, a second fan, a second electric motor assembly supported by the frame and operably connected to the second fan, and a liquid cooling path that passes adjacent to both a first stator of the first electric motor assembly and a second stator of the second electric motor assembly such that thermal energy is transferable from the first electric motor assembly and the second electric motor assembly to a liquid coolant present in the liquid cooling path. Other aspects of an electric cooling fan system and associated method of making the same are also disclosed.

### FIELD

The present invention generally relates to high voltage electric fan systems, and components thereof, suitable for cooling applications, as well as associated methods of making and using the same.

### BACKGROUND

Initiatives are underway to limit greenhouse gas emissions and other types of emissions, including CO₂ and NOx emissions. In pursuit of those objectives, alternative powertrains are being developed to replace an internal combustion engine. These include powertrain applications for vehicles like heavy-duty trucks and off-highway vehicles such as construction and mining equipment (for example, excavators, graders, loaders, and mining vehicles) with relatively high torque capacities. A need exists to provide cooling for a variety of systems on these types of equipment and vehicles. Electric powertrains on such vehicles typically consist of motors, electronic drives (often referred to as inverters), and mechanical transmissions. These devices are powered by an energy source such as a battery or fuel cell. Those energy sources are typically carried on the vehicle along with the electric powertrain. The power sources have an energy loss during the conversion of energy. For example, in the case of a battery, there is a loss of energy during the conversion of electricity to or from chemical energy during charging and dis-charging. In the case of a fuel cell, there is an energy loss during the conversion of hydrogen and oxygen to water. In both cases, energy loss in the form of heat (thermal energy) can be substantial and require significant cooling to protect impacted systems from thermal damage. Though particularly in the case of battery-powered vehicles, battery charging operations may have significant cooling demands even when the vehicle is otherwise idle. Operation of auxiliary systems such as supplemental braking mechanisms (e.g., for vehicle operation in mountainous areas) or various other on-board systems may also have cooling demands that extend beyond the basic powertrain and power source cooling demands.

Additionally, such drivetrains are presently intended to operate at high voltages in order to constrain the size of electrical conductors, typically in the range of approximately 650 to 900 volts direct current (VDC). Though because development of these drivetrains is ongoing, other relatively high voltages might be utilized as well, such as even higher voltages. On-board vehicle cooling systems will generally be powered by the same on-board energy sources as the electric powertrain, and will therefore operate at the same high voltages. However, equipment developed for use as electric traction motors in the vehicle powertrain is not readily suited to use in cooling systems. Vehicle traction motors have relatively high torque requirements and take up considerable space. In contrast, cooling systems that provide fan-driven air flows have lower torque requirements, and are subject to substantial space constraints. Bulky and heavy electric traction motor components used in a primary powertrain are therefore ill-suited to use in fan cooling systems that are, essentially, auxiliary systems. On the other hand, lower voltage systems are not directly adaptable to high-voltage use, particularly for use in vehicular applications. Indeed, there is a general lack of high voltage componentry suitable for the torque, space, and mass constraints that apply to fan cooling systems, in addition to a lack of available high voltage electric fan systems (as a whole) suitable for use in vehicular applications.

It is desired to provide a cooling system powered using high voltage electric power that occupies a relatively small amount of space and operates with relatively high efficiency. Such a high voltage cooling system should be suitable for use in vehicular applications, as well as comparable non-vehicular industrial cooling applications. Liquid cooling and a suitable frame for mounting and supporting various components are also desired as part of such a high voltage cooling system. Additionally, accommodation for both high and low voltage electrical components in the same system, while reducing electromagnetic interference and still providing a relatively compact physical electronics assembly, is desired. Moreover, it is desired to provide methods of making and using such a high voltage cooling system.

### SUMMARY

In one aspect, an electric cooling fan system can include a frame, a first fan, a first electric motor assembly supported by the frame and operably connected to the first fan, a second fan, a second electric motor assembly supported by the frame and operably connected to the second fan, and a liquid cooling path that passes adjacent to both a first stator of the first electric motor assembly and a second stator of the second electric motor assembly such that thermal energy is transferable from the first electric motor assembly and the second electric motor assembly to a liquid coolant present in the liquid cooling path.

In another aspect, a liquid-cooled electric fan system can include an electric motor, a fan, an electronics enclosure, and a liquid cooling channel. The electric motor can include a rotor with a rotor shaft, a stator, and a motor housing. The rotor can be positioned adjacent to the stator, and the motor housing can at least partially surround the rotor and the stator. The fan can be operably connected to the rotor shaft such that a torque output from the electric motor can rotate the fan. The electronics enclosure can be attached to the motor housing, with the electronics enclosure including inverter circuitry electrically connected to the electric motor. The liquid cooling channel can be positioned between the inverter circuitry and the stator, and the liquid cooling channel can contain a liquid coolant capable of accepting thermal energy from one or both of the electric motor and the inverter circuitry.

In another aspect, an electric cooling fan system can include a frame, a first electric motor, and a first fan. The frame can include a pair of crossbars spaced from each other in a substantially parallel arrangement and a plurality of legs each connected to both of the crossbars. At least one of the plurality of legs can include a tube having a nonlinear shape, and all tubular portions of the frame can be closed against liquid incursion. The first electric motor can be attached to both of the crossbars. The first fan can be operably connected to the first electric motor, such that a torque output from the first electric motor can rotate the first fan.

In another aspect, an electric fan system can include an electric motor, a fan, and an electronics assembly. The electric motor can include a rotor, a stator, and a motor housing. The rotor can be positioned adjacent to the stator, and the motor housing can at least partially surround the rotor and the stator. The fan can be operably connected to the electric motor such that a torque output from the electric motor can rotate the fan. The electronics assembly can include a base, a cover attached to the base, a high voltage electrical connector, a low voltage electrical connector, inverter circuitry, and communications circuitry. The base and the cover can enclose an interior volume, and the electric fan system can be configured such that the interior volume is sealed against liquid incursion. The high voltage electrical connector can pass through either the base or the cover, and the low voltage electrical connector can pass through either the base or the cover. The inverter circuitry can be located in the interior volume and electrically connected to both the electric motor and the high voltage electrical connector, and the inverter circuitry can be configured to generate a power output at greater than or equal to 850 Volts DC. The communications circuitry can be located in the interior volume and electrically connected to both the inverter circuitry and the low voltage electrical connector, and the communications circuitry can be configured to operate at less than 500 Volts DC.

An electronics assembly can include an enclosure having an interior volume and being liquid-tight, inverter circuitry located within the interior volume with at least a portion of the inverter circuitry configured to operate at high voltages greater than 600 VDC, communications circuitry located within the interior volume and configured to operate at low voltages less than 500 VDC, high voltage electromagnetic interference (EMI) filter circuitry located within the interior volume and electrically connected between a high voltage power input and the inverter circuitry, and low voltage EMI filter circuitry located within the interior volume and electrically connected between a low voltage power input and the communications circuitry. The high voltage EMI filter circuitry can include at least one common mode choke inductor coil, at least one differential mode X capacitor, and at least one common mode Y capacitor. The low voltage EMI filter circuitry can include at least one common mode choke inductor coil and at least one common mode Y capacitor. The low voltage EMI filter circuitry can have a different configuration than the high voltage EMI filter circuitry.

In yet another aspect, a method of making an electric cooling fan system can include bending metallic tubes to form a plurality of legs having nonlinear shapes, securing a pair of crossbars spaced from each other in a substantially parallel arrangement to each of the plurality of legs, after the pair of crossbars are secured to the plurality of legs, welding end pieces to open ends of the plurality of legs to create a frame, such that all tubular portions of the frame are closed against liquid incursion, attaching a first electric motor assembly to each of the crossbars after the frame is created, and operably connecting a first fan to the first electric motor assembly. Each of the end pieces can have a fastener opening to accept a mechanical fastener suitable to mount the frame at a mounting location.

The present summary is provided only by way of example, and not limitation. Other aspects of the present invention will be appreciated in view of the entirety of the present disclosure, including the entire text, claims, and accompanying figures.

### BRIEF DESCRIPTION OF THE DRAWINGS

FIG. 1A is a schematic block diagram of an embodiment of a high voltage electric cooling fan system with dedicated electronics assemblies.

FIG. 1B is a schematic block diagram of another embodiment of a high voltage electric cooling fan system using a shared electronics assembly.

FIG. 2 is a schematic block diagram of an embodiment of the present high voltage cooling fan system in an example vehicular application.

FIGS. 3A and 3B are front and rear perspective views, respectively, of a portion of an embodiment of a single-fan high voltage cooling fan system with a combined motor assembly and electronics assembly unit.

FIGS. 4A and 4B are rear and front perspective views, respectively, of a portion of an embodiment of a dual-fan high voltage cooling fan system with a remotely-mounted electronics assembly.

FIG. 4C is a perspective view of a portion of a frame of FIGS. 4A and 4B.

FIG. 4D is a sectional view of the portion of the frame, taken along line 4D-4D of FIG. 4C.

FIG. 4E is a sectional view of a portion of the electronics assembly of FIGS. 4A and 4B, taken along line 4E-4E of FIG. 4A.

FIG. 5A is a rear elevation view of an electric motor assembly and attached fan of the embodiment of FIGS. 4A and 4B, shown in isolation.

FIG. 5B is a sectional view of an electric motor assembly and the fan, taken along line 5B-5B of FIG. 5A.

FIG. 5C is a sectional view of the electric motor assembly and the fan, taken along line 5C-5C of FIG. 5B.

FIG. 6A is a rear perspective view of a portion of an embodiment of a dual-fan system having a liquid cooling circuit configured in series.

FIG. 6B is a rear perspective view of a portion of an embodiment of a dual-fan system having a parallel liquid cooling circuit configuration.

FIG. 7 is an exploded perspective view of the electronics assembly of FIGS. 4A and 4B, shown in isolation.

FIG. 8 is a rear perspective view of an alternate embodiment of a dual-fan high voltage cooling fan system.

FIGS. 9A and 9B are side elevation and cross-sectional views, respectively, of portions of the high voltage cooling fan system of FIG. 8, shown in isolation, illustrating an embodiment of an electric motor assembly and an electronics assembly packaged together in a combined unit.

FIGS. 10A-10C illustrate portions of an embodiment of a dedicated electronics assembly for use with a combined motor assembly/electronics assembly unit; FIGS. 10A and 10B are top perspective views (shown with a cover and various internal components omitted) and FIG. 10C is a sectional view of the electronics assembly taken along line 10C-10C of FIG. 10B.

FIG. 11A is a schematic illustration of an embodiment of a shared electronics assembly of a high voltage electric cooling fan system.

FIG. 11B is a schematic illustration of another embodiment of a dedicated electronics assembly of the high voltage electric cooling fan system.

FIG. 12A is a schematic illustration of an embodiment of high voltage EMI filter circuitry.

FIG. 12B is a schematic illustration of an embodiment of low voltage EMI filter circuitry.

FIG. 13A is a perspective view of an embodiment of a ferrite assembly.

FIG. 13B is a perspective view of a portion of a holder of the ferrite assembly of FIG. 12A.

While the above-identified figures set forth one or more embodiments of the present invention, other embodiments are also contemplated, as noted in the discussion. In all cases, this disclosure presents the invention by way of representation and not limitation. It should be understood that numerous other modifications and embodiments can be devised by those skilled in the art, which fall within the scope and spirit of the principles of the invention. The figures may not be drawn to scale, and applications and embodiments of the present invention may include features, steps and/or components not specifically shown in the drawings.

### DETAILED DESCRIPTION OF ILLUSTRATIVE EMBODIMENTS

In general, the design of the presently-disclosed high voltage electric cooling fan system includes one or more electrically driven fans designed to operate on direct current supply voltages between approximately 500-1200 Volts direct current (VDC), such as at approximately 900 VDC. During operation, the high voltage electric cooling fan system can generate airflows, for instance, moving cooling air past a heat exchanger. The overall system includes at least one fan, a motor assembly, an electronics assembly (with power electronics including a motor drive or inverter, electromagnetic interference filtering hardware, plus communications circuitry, etc.), and structural components sufficient to accept the various components and secure the overall system to a mounting location. In a typical vehicular application, the motor assembly can be secured with a mounting structure that allows it to be mounted to a heat exchanger or some other on-board structural member. In some embodiments, the cooling fan system includes a guard to keep fingers and other appendages or objects from contacting the rotating fan blades. In order to allow for different implementations, the electronics assembly can be positioned differently in relation to the motor assembly. In some embodiments, the motor assembly and an enclosure of the electronics assembly can be structurally attached together as a combined unit while, in other embodiments, the inverter can be remotely mounted and be linked to the motor via cables, hoses, and/or the like. A primary consideration for this difference is the amount of space available for the cooling system, particularly in an axial direction. A liquid cooling circuit can also be provided by the high voltage electric cooling fan system, in order to help regulate thermal operating conditions and cool the electronics assembly and/or the motor assembly. Numerous other features and benefits will be appreciated by those of ordinary skill in the art in light of the entirety of the present disclosure, including the accompanying figures.

In some applications the high voltage electric cooling fan system is carried on board a vehicle with an electrically-powered powertrain, such as inside a motor compartment that could additionally contain an electrically-powered traction motor, at least one heat exchanger assembly, and/or other on-board components. It should be noted, however, that the high voltage electric cooling fan system can also be utilized in non-vehicular industrial cooling applications as well, such as to cool manufacturing equipment in a factory, for example.

The present application claims priority to U.S. provisional patent application Ser. No. 63/269,575, filed Mar. 18, 2022, which is hereby incorporated by reference in its entirety.

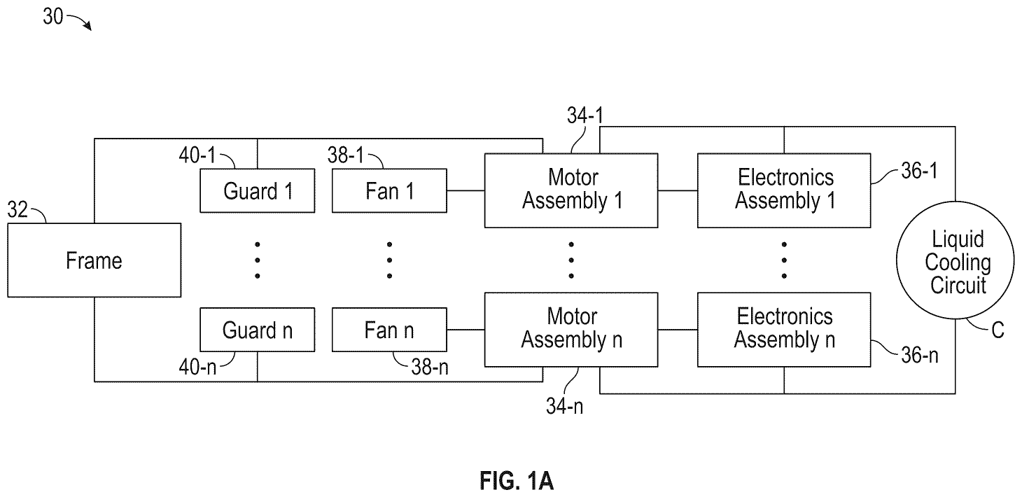

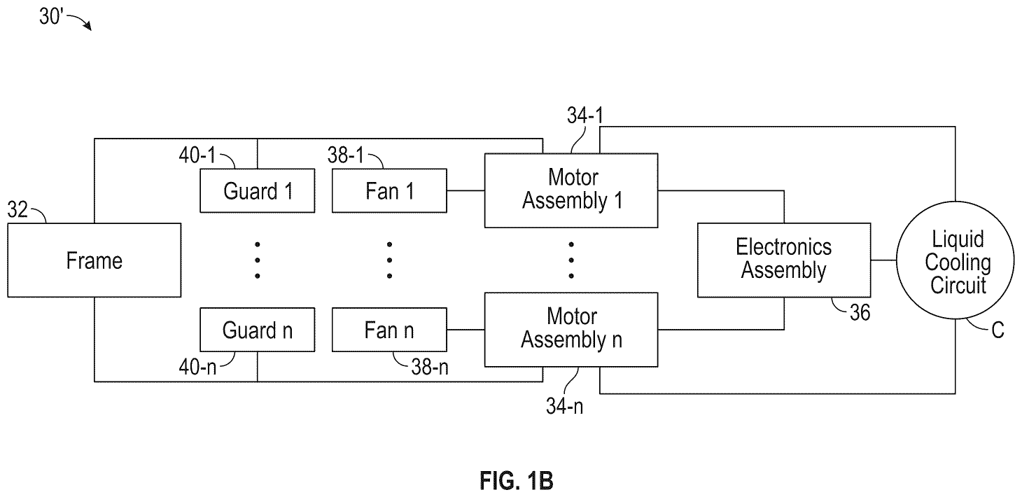

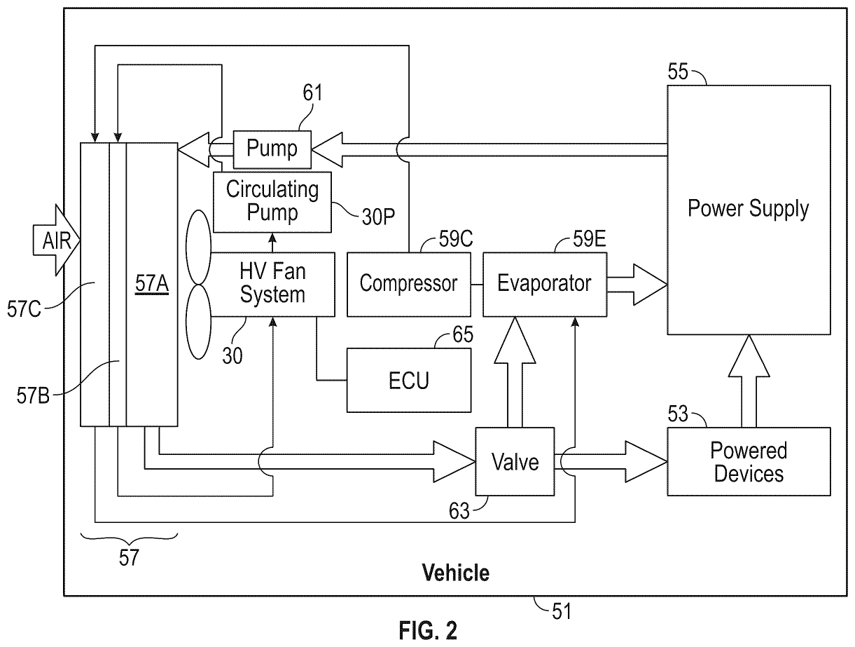

FIGS. 1A and 1B are schematic block diagrams of embodiments of high voltage electric cooling fan systems 30 and 30′. As shown in the embodiment of FIG. 1A, the high voltage electric cooling fan system 30 includes a frame (or mounting frame) 32, one or more electric motor assemblies 34-1 to 34-n, one or more electronics assemblies 36-1 to 36-n, and one or more fans 38-1 to 38-n (which can each optionally be protected by a guard 40-1 to 40-n). The total number of discrete fan subassemblies n can be n≥1, such that single-fan and multi-fan embodiments are encompassed. Furthermore, a liquid cooling circuit C can be provided for the high voltage electric cooling fan system 30, and that liquid cooling circuit C can be operatively coupled to a liquid/air heat exchanger and a liquid circulation pump (not depicted in FIG. 1A or 1B, but see, e.g., FIG. 2). In some embodiments, such as the embodiment shown in FIG. 1A, the high voltage electric cooling fan system 30 has one electric motor assembly 34-1 to 34-n and one electronics assembly 36-1 to 36-n for each fan 38-1 to 38-n, which can include single-fan and multi-fan embodiments of the system 30. In other words, in such embodiments like that shown in FIG. 1A there is a dedicated electronics assembly 36-1 to 36-n for each electric motor assembly 34-1 to 34-n. As shown in FIG. 1B, the high voltage electric cooling fan system 30′ generally includes the same components as the embodiment shown in FIG. 1A except that there is only a single shared electronics assembly 36 when the number of fan subassemblies is n≥2.

The electric motor assembly or assemblies 34-1 to 34-n are each operable to produce torque to drive a corresponding fan 38-1 to 38-n, with variable control over fan speed, rotational direction, and the like. In the embodiment of FIG. 1A, the electronics assembly or assemblies 36-1 to 36-n are each operably connected to a corresponding electric motor assembly 34-1 to 34-n and control operation of that motor assembly 34-1 to 34-n in a dedicated manner, including by supplying power to the corresponding electric motor assembly 34-1 to 34-n and by controlling associated communications (e.g., associated command signals, sensor signals, or the like). Though in the alternate embodiment shown in FIG. 1B, a single combined or shared electronics assembly 36 is provided that drives and controls multiple motor assemblies 34-1 to 34-n when the number of fan subassemblies is n≥2.

The frame 32 supports at least the electric motor assembly or assemblies 34-1 to 34-n, which in turn support the corresponding fan(s) 38-1 to 38-n. The electronics assembly or assemblies 36 or 36-1 to 36-n can be supported by the frame 32 or, alternatively, supported elsewhere (that is, remote from the frame 32), in different embodiments. In the illustrated embodiments, a liquid cooling circuit C is fluidically connected to each of the electric motor assemblies 34-1 to 34-n and each electronics assembly or assemblies 36 or 36-1 to 36-n to form a single or common fluid circuit, though in alternate embodiments multiple, separate liquid cooling circuits could be utilized for certain components of the system 30 or 30′.

The high voltage electric cooling fan system 30 or 30′ is electrically powered by an external power supply (not shown in FIGS. 1A and 1B). In vehicular applications, the external power supply would typically be an on-board power supply such as batteries, fuels cells, or the like, which would typically be shared with other on-board electrically-powered systems including, for example, a powertrain with an electrically-powered traction motor. Though a dedicated on-board power supply or other means of power supply could be utilized to power the system 30 or 30′ in further embodiments. In some embodiments, the external power supply delivers high voltage direct current to the high voltage electric cooling fan system at approximately 500-1200 Volts DC (for example, at approximately 850 VDC or approximately 900 VDC).

It should be noted that FIGS. 1A and 1B merely illustrate two example embodiments of the inventive cooling fan system 30 or 30′ at a relatively high level of abstraction. Various additional components, features, and alternate configurations of the high voltage electric cooling fan system 30 or 30′ are described elsewhere in the present disclosure, or would be understood by persons of ordinary skill in the art to be usable with the disclosed system 30 or 30′ as desired for particular applications.

FIG. 2 is a schematic block diagram of an embodiment of the high voltage cooling fan system 30 in an example vehicular application. Although the system 30 is denoted in FIG. 2, it is shown only by way of example and the system 30′ could be utilized instead in alternative embodiments. As shown in the embodiment of FIG. 2, a vehicle 51 has various on-board systems including electrically-powered devices 53 (such as a traction motor, other types of electric motors, an electric heater, control/power electronics, etc.), a high voltage electrical power supply 55 (e.g., batteries and/or fuel cells), a heat exchanger assembly 57, and the high voltage electric cooling fan system 30 with an associated circulating pump 30P. Various additional on-board systems, including a compressor 59C, an evaporator 59E, pump 61, an optional valve 63, etc., are illustrated in FIG. 2 as examples of components that could be used as part of separate on-board cooling systems used in addition to the high voltage electric cooling fan system 30. Moreover, an example electronic control unit (ECU) 65 with processing and control functionality is shown (e.g., an on-board vehicle computer). Although not depicted separately in FIG. 2, the power supply 55 can include an inductive charging subsystem in some embodiments where the power supply 55 includes batteries. Moreover, for simplicity, electrical connections to the power supply 55 are not specifically shown in FIG. 2, nor are all electrical signal connections to the ECU 65.

In some embodiments, the heat exchanger assembly 57 can include multiple discrete liquid/air heat exchangers arranged as an axial stack and/or in a side-by-side array. FIG. 2 illustrates an embodiment with an axially stacked heat exchanger assembly 57 that includes first and second liquid-to-air heat exchangers (or radiators) 57A and 57B, and a condenser 57C. Various heat exchangers 57A-57C in the heat exchanger assembly 57 may have different operating temperatures. In the illustrated embodiment, for instance, the condenser 57C can operate with the compressor 59C and the evaporator 59E as part of a chiller or air conditioning system. In vehicular applications, the heat exchanger assembly 57 is carried on-board the vehicle 51 and can be utilized to remove thermal energy from coolant fluids (for instance, liquid coolant) that carry thermal energy away from on-board systems, such as the radiator 57A removing waste heat from liquid coolant used to cool the traction motor, the power supply 55 (and an associated induction charging system if present), climate control systems (e.g., for cabin air conditioning, cargo refrigeration), and/or other systems.

As shown in FIG. 2, the high voltage electric cooling fan system 30 can be positioned near the heat exchanger assembly 57 in order to move cooling air through the heat exchanger assembly 57. In embodiments where the high voltage electric cooling fan system 30 includes a liquid cooling circuit C, that liquid cooling circuit C can be tied to at least one liquid/air heat exchanger (radiator) 57B in the heat exchanger assembly 57. In this way, the high voltage electric cooling fan system 30 provides its own cooling, at least in part, by generating cooling airflows that act upon the liquid/air heat exchanger (radiator) 57B that rejects waste heat from the liquid cooling circuit C for that very same high voltage electric cooling fan system 30. The circulating pump 30P is fluidically connected to the liquid cooling circuit C and allows the liquid coolant to be circulated through the liquid cooling circuit C. The circulating pump 30P can be located in any suitable on-board location in vehicular applications, but in some embodiments the circulating pump can be located remotely from the fan(s) 38-1 to 38-n, the electric motor assembly or assemblies 34-1 to 34-n, and the frame 32 of the high voltage electric cooling fan system 30. Moreover, the circulating pump 30P and/or the liquid cooling circuit C could be shared with other on-board systems in some embodiments, such as integrating the circulating pump 30P and the pump 61.

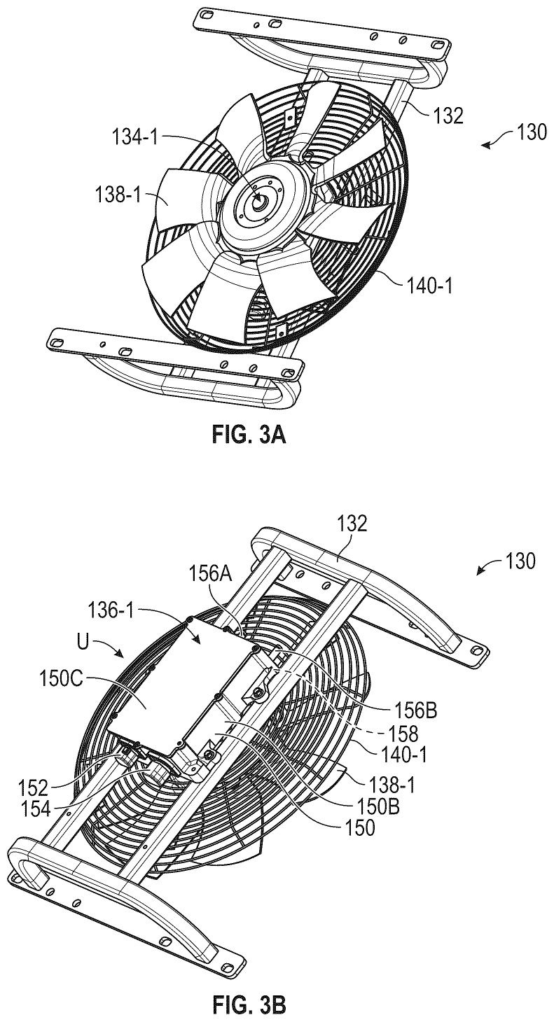

A single-fan embodiment of a high voltage electric cooling fan system 130 is shown in FIGS. 3A and 3B. In that illustrated embodiment, an electronics assembly 136-1 is located adjacent to the electric motor assembly 134-1 and is carried on the frame 132. As shown the electronics assembly 136-1 is attached to the electric motor assembly 134-1, which in turn is attached to the frame 132. The electronics assembly 136—and the electric motor assembly 134-1 can be integrated as a combined unit U. A fan 138-1 is operatively attached to the electric motor assembly 134-1, and is partly or completely surrounded by a guard 140-1. The electronics assembly 136-1 includes an enclosure 150 with a base 150B and a cover 150C, with a low voltage connector 152 and a high voltage connector 154 providing liquid-tight electrical connections through an external wall or walls of the enclosure 150. Suitable electric cable (not shown) can be engaged with the connectors 154 and 156 to provide electric power inputs and/or carried electric signals, such as two-way communications with an external engine controller of a vehicle. Inlet and outlet ports 156A and 156B are also provided for a liquid cooling channel 158 that extends into at least one wall of the enclosure 150 (e.g., an external wall), such as at a front side of the base 150B that faces the electric motor assembly 134-1. A liquid cooling path is thus provided through or adjacent to both the electronics assembly 136-1 and the electric motor assembly 134-1 that can be connected to the liquid cooling circuit C with suitable hoses or the like (not shown), such that a liquid coolant present in the liquid cooling channel 158 that can flow along the liquid cooling path and the liquid cooling circuit C can accept thermal energy from one or both of the electronics assembly 136-1 and/or the electric motor assembly 134-1 to carry away waste heat and regulate operating temperatures of such components.

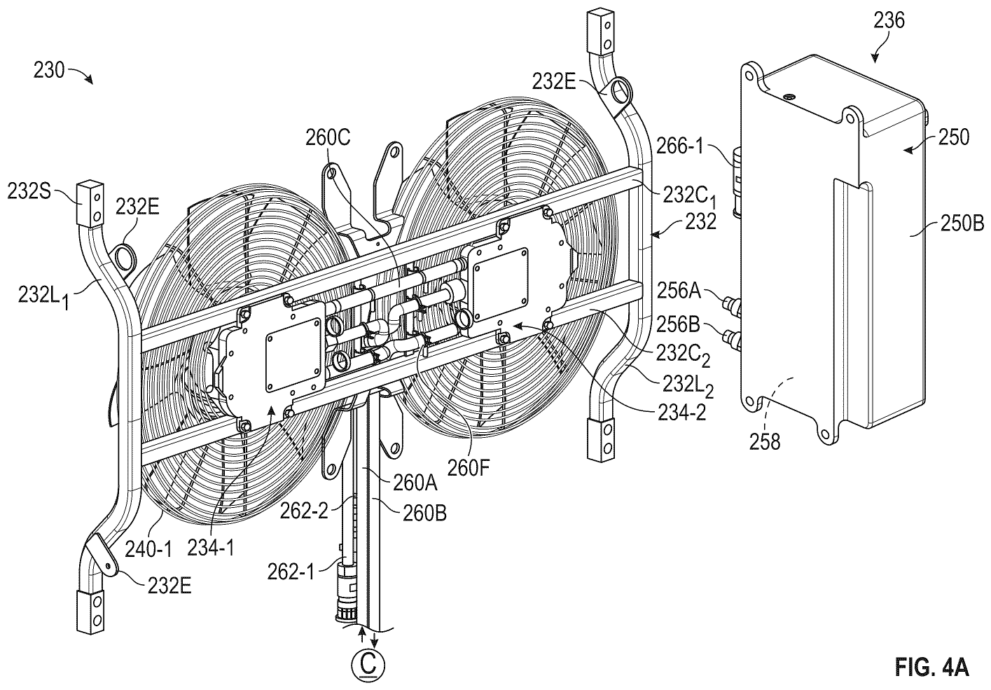

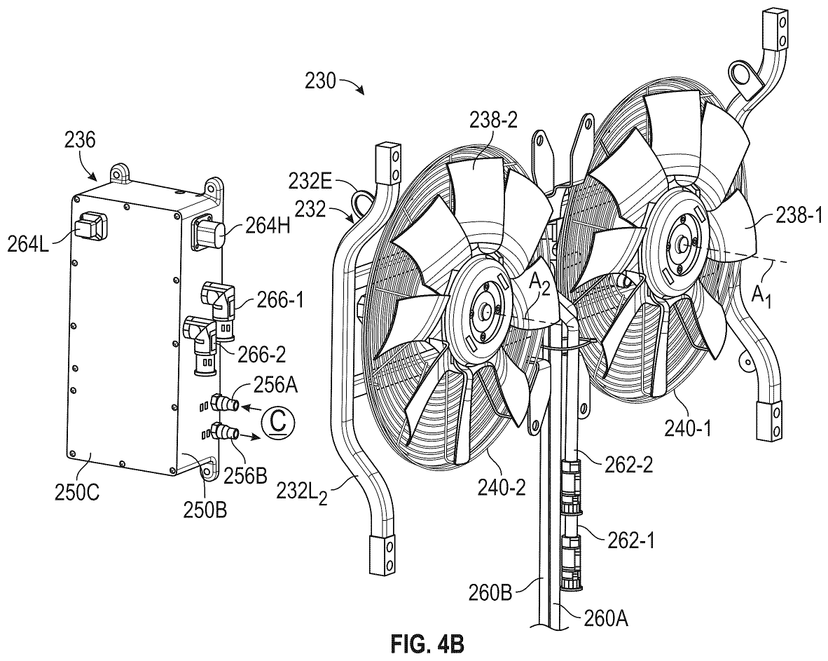

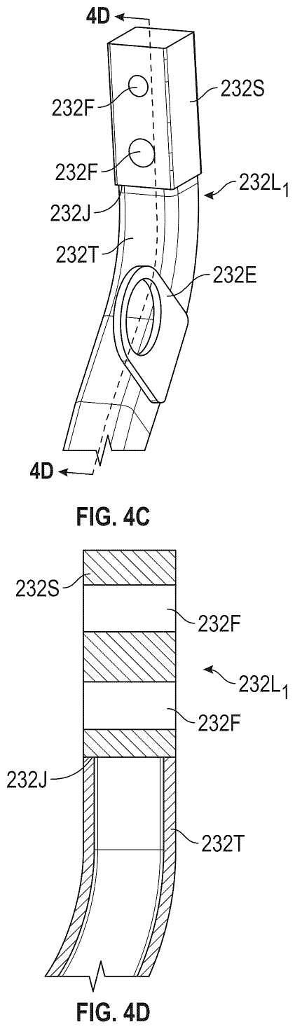

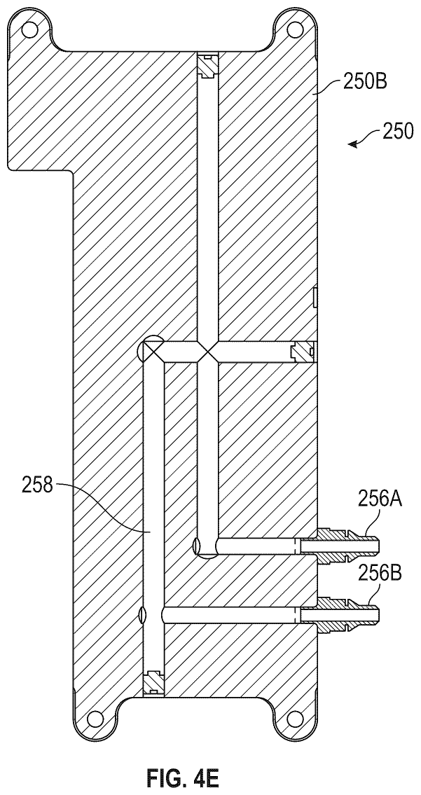

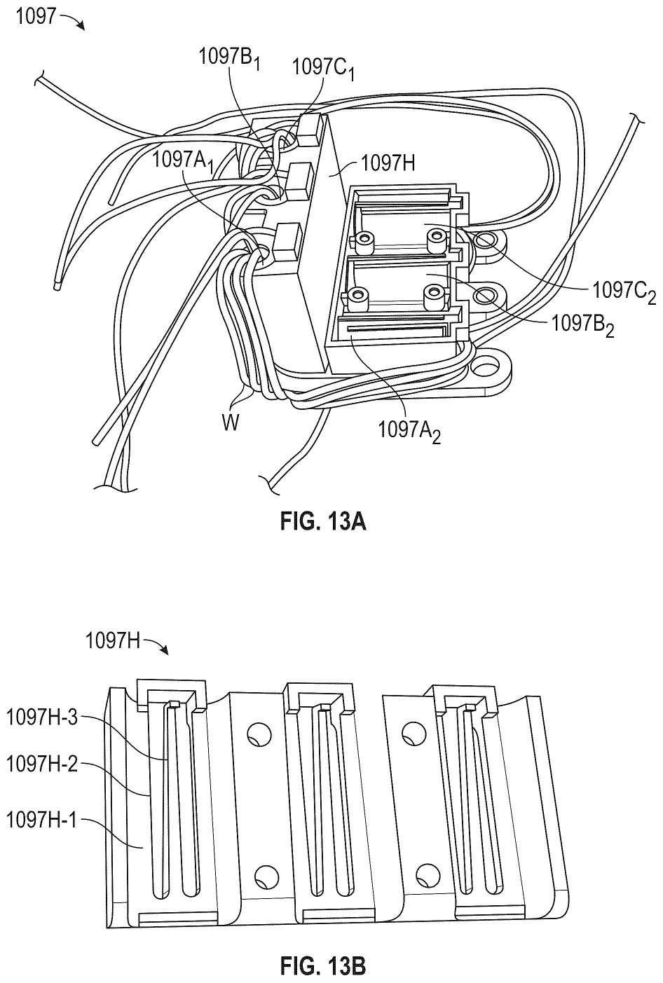

Most of the discussion that follows refers to dual-fan embodiments shown in other figures (see, e.g., FIGS. 4A, 4B, and 13). However, features and configurations described and shown with respect to multi-fan embodiments are generally applicable to single-fan embodiments like that of FIGS. 3A and 3B as well, except where features are specific to components that are shared between components associated with multiple discrete fans in a single system. It should be noted that FIGS. 3A and 3B show only a rear half of the guard 140-1 for the fan 138-1, but embodiments can include a guard 140-1 that further includes a front cover portion (not shown) to enclose the fan 138-1 on both sides.

In general, multi-fan embodiments can include two or more fans and two or more associated high voltage electric fan motors (providing a fan array) that are attached and mounted to a common frame. One advantage of a multi-fan configuration (such as a dual-fan embodiment) is that smaller fans and fan motors can occupy less axial space than a single larger fan with a larger fan motor. The more compact (and, especially, more axially compact) configuration of a multi-fan embodiment can help accommodate packaging and installation space constraints, which are often significant in on-board vehicular applications. The fans and fan motors utilized in multi-fan embodiments can each be the same size and power in some embodiments. Though, in further embodiments, the fans and/or fan motors could alternatively be different sizes (and/or have different power capabilities). Each fan and electric motor assembly in the multi-fan array (see, e.g., FIG. 13) can generally contain the same elements as the single-fan embodiment (see, e.g., FIGS. 3A and 3B), including the fan or fans, fan motor assembly or assemblies, electronics assembly or assemblies, etc. However, some of the components can be shared between components of the multi-fan arrays in some embodiments (see, e.g., FIGS. 4A and 4B), such as a single-entry point for the coolant as well as combined routing for the power and communications cables. Moreover, a single combined or shared electronics assembly (see, e.g., FIG. 1B) can be used to drive and control multiple fan motors in some embodiments, such as with embodiments in which a remotely-located combined electronics assembly controls multiple electric motor assemblies.

FIGS. 4A and 4B are rear and front perspective views, respectively, of a portion of a dual-fan embodiment of a high voltage electric cooling fan system 230 with an electronics assembly 236 that is remotely mountable. FIG. 4C is a perspective view of a portion of a frame 232 of the electric cooling fan system 230 and FIG. 4D is a sectional view taken along line 4D-4D of FIG. 4C. FIG. 4E is a sectional view of a portion of the electronics assembly 236 taken along line 4E-4E of FIG. 4A. As shown in the illustrated embodiment of FIGS. 4A-4E, the electric cooling fan system 230 includes the frame 232, first and second electric motor assemblies 234-1 and 234-2, the electronics assembly 236, first and second fans 238-1 and 238-2, and first and second guards 240-1 and 240-2.

As shown in the illustrated embodiment, the frame 232 includes first and second crossbars 232C₁ and 232C₂ (which can also be referred to as main tubes in some embodiments), first and second legs 232L₁ and 232L₂, and lifting eyelets 232E. The crossbars 232C₁ and 232C₂ can be arranged substantially parallel to each other and spaced from each other (e.g., spaced vertically) and can extend generally horizontally when the frame 232 is installed at a desired mounting location. The legs 232L₁ and 232L₂ can each be connected to each of the crossbars 232C₁ and 232C₂, such as with the legs 232L₁ and 232L₂ welded or brazed at or near opposite ends of the crossbars 232C₁ and 232C₂. In the illustrated embodiment, the crossbars 232C₁ and 232C₂ each have a substantially linear shape and be configured as tubes while the legs 232L₁ and 232L₂ each have a nonlinear shape with a middle section and ends that are offset from the middle section by way of bends (e.g., curved portions). At least portions of each of the legs 232L₁ and 232L₂ and/or the crossbars 232C₁ and 232C₂ can be configured as tubes, that is, hollow, and can be made of a metallic material such as steel. In the illustrated embodiment, tubes forming the legs 232L₁ and 232L₂ and the crossbars 232C₁ and 232C₂ have a substantially rectangular (e.g., square) cross-sectional profile. The nonlinear shapes of the legs 232L₁ and 232L₂ can allow the frame 232 to be mounted to a structure located generally in front of the electric cooling fan system 230 (e.g., a heat exchanger such as the heat exchanger assembly 57 shown in FIG. 2) while positioning the crossbars 232C₁ and 232C₂ at locations spaced (e.g., axially spaced) from such a structure to allow space for the fans 238-1 and 238-2 and the like. In the illustrated embodiment, the electric motor assemblies 234-1 and 234-2 are each attached and supported on the crossbars 232C₁ and 232C₂ with suitable fasteners (e.g., bolts, screws), with at least portions of each of the electric motor assemblies 234-1 and 234-2 located in between the crossbars 232C₁ and 232C₂. The crossbars 232C₁ and 232C₂ can have elongate shapes and considerable length to allow the electric motor assemblies 234-1 and 234-2 to be connected and arranged in a side-by-side configuration while still allowing the fans 238-1 and 238-2 to rotate without interference, such as in a side-by-side arrangement with the fans 238-1 and 238-2 having respective axes of rotation A₁ and A₂ that can be substantially parallel to each other. The frame 232 provides a sufficiently strong structural framework to support some or all of the components of the electric cooling fan system 230 while remaining relatively compact, particularly in an axial direction, and relatively low in mass.

The frame 232 can also include provisions for lifting the entire electric cooling fan system 230, which can facilitate assembly within a vehicle compartment in which other installed components present obstacles to the maneuvering of the system 230. Because the frame 232 and components of the system 230 carried by it can have a relatively large mass in total, the lifting eyelets 232E can be provided, such as on at least upper ends of the legs 232L₁ and 232L₂, which can facilitate attaching a lifting mechanism like a hoist or crane to lift and maneuver the frame 232 and frame-supported components of the electric cooling fan system 230 into place in a desired mounting location, such as in a motor compartment of a vehicle, where space constraints due to the presence of other objects may limit maneuverability. The provision of multiple eyelets 232E in different locations can facilitate lifting frame 232 and attached components of the system 230 in different orientations, such as horizontal and vertical. In some embodiments, lifting eyelets facing in different directions (for example, orthogonal to each other) can be provided to allow lifting the system 230 in different orientations, such as with the system 230 in either a horizontal or vertical orientation.

Furthermore, there is a desire to keep moisture out of the inside of the mounting structure in order to prevent internal corrosion. In vehicular and similar applications, for instance, the frame 232 may be exposed to extreme environmental conditions. In some embodiments, for example, one or more tubular portions of the frame 232 can be closed or otherwise sealed to block liquid incursion. As shown in the illustrated embodiment in FIGS. 4A-4D, at least one of the legs 232L₁ and 232L₂ can have a tubular portion 232T that is attached to a solid end piece or portion 232S at a sealed connecting interface 232J, such as a welded or brazed joint, that substantially blocks liquid incursion into the tubular portion 232T. The solid end portion 232S can have one or more openings 232F through it to accept fasteners such as bolts or the like that can be used to secure the entire frame 232 to a desired mounting location. Because the overall system 230 can have considerable mass, such fasteners may need to apply a substantial clamping force on the frame 232, and the solid end portions 232S can help withstand such loading better than the tubular portion 232T. But the combined use of solid and tubular portions at different locations on the frame 232 allows for mass reduction while still providing adequate structural integrity. In some embodiments, the legs 232L₁ and 232L₂ can be bent or otherwise formed into a non-linear shape prior to the solid end portions 232S being attached (e.g., welded or brazed), and furthermore the legs 232L₁ and 232L₂ can also be attached (e.g., welded or brazed) to the crossbars 232C₁ and 232C₂ prior to the solid end portions 232S being attached (e.g., welded or brazed). This approach to manufacturing has been discovered to allow for improved tolerancing of the entire frame 232, by accommodating flexing and/or warping that can occur to the frame 232 during welding or brazing, particularly at or near the ends of the legs 232L₁ and 232L₂ where attachment points are located, that could otherwise result in desired tolerances being missed. For example, in some embodiments, the frame 232 can be fabricated by bending the legs 232L₁ and 232L₂ to desired shapes, then securing the crossbars 232C₁ and 232C₂ to the legs 232L₁ and 232L₂, such as by welding or brazing or alternatively with mechanical attachments such as fasteners, clamps, or the like, and then, subsequently, the solid end portions 232S can be attached to the legs 232L₁ and 232L₂.

Additionally, or in the alternative, thread forming screws or the like can be used to help prevent liquid from entering hollow portions of the frame 232 in embodiments where such screws or similar fastener elements connect the electric motor assemblies 234-1 and 234-2 to the crossbars 232C₁ and 232C₂ and pierce the tubular crossbars 232C₁ and 232C₂. However, use of thread forming screws can be limited to only the attachment of relatively smaller components like the electric motor assemblies 234-1 and 234-2, and omitted from attachment points for mounting the entire frame 232 to a desired mounting location, due to the need for greater forces to secure the mass of most or all of the electric cooling fan system 230.

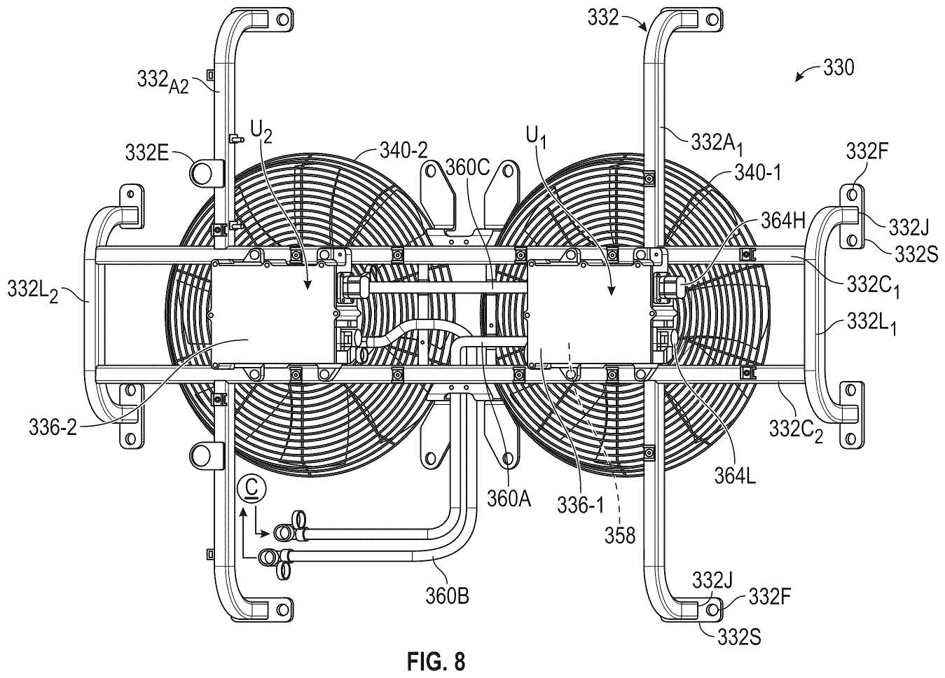

Alternatively, end plugs inserted into and secured to tubular end portions of the legs can be used in further embodiments to provide stiffening to help prevent the leg tubes from collapsing when mounting fasteners (e.g., screws, bolts, rivets, etc.) are tightened. Such end plugs can also act as a barrier for fluids to enter the mounting structure through an end opening or through fastener openings. In some embodiments, fastener openings can pass through both the end plugs and the tubing. In further embodiments, end flanges can be provided at ends of the tubular portions 232T of the legs 232L₁ and 232L₂ that both close the ends of the tubing (with or without plugs extending into the tubing) and which can provide attachment points oriented at an angle (e.g., at) 90° relative to the tubing of the corresponding leg, such as shown in FIG. 8. In still further embodiments, combinations of one or more types of these liquid sealing, structural strengthening, and/or fastener orientation accommodation features can be utilized in a given implementation.

The frame 232 can serve multiple functions. First and foremost, the frame 232 supports the fans 238-1 and 238-2 and the electric motor assemblies 234-1 and 234-2 and places them in desired positions relative to a mounting location of the system 230, such as to properly position the fans 238-1 and 238-2 relative to a vehicle heat exchanger assembly (e.g., the heat exchanger assembly 57 of FIG. 2). Other components can also optionally be secured directly or indirectly to the frame 232 including the guards 240-1 and 240-2, the liquid coolant line hoses 260A and 260B (which can be routed through the fittings 260F that can be attached to the frame 232), the high voltage electrical cables (e.g., the cables 262-1 and 262-2) and/or low voltage electrical cables (any or all of which can be routed through cable guides attached to the frame 232), a fan shroud support, vehicle heat exchanger mid-width stabilization supports, the electronics assembly 236, etc.

The first and second electric motor assemblies 234-1 and 234-2 are each high voltage motor assemblies that are capable of generating torque to rotate the corresponding first and second fans 238-1 and 238-2. In the illustrated embodiment, the first and second electric motor assemblies 234-1 and 234-2 are substantially identical to each other and are arranged side-by-side in a horizontal mirror image relationship, although they can differ from each other and/or be arranged differently in further embodiments. Other components of the electric motor assemblies 234-1 and 234-2 are discussed later in the present disclosure. A number of hoses 260A, 260B, and 260C can be provided to connect liquid cooling channels of each of the electric motor assemblies 234-1 and 234-2 to the liquid cooling circuit C. Moreover, cables 262-1 and 262-2 can electrically connect the respective electric motor assemblies 234-1 and 234-2 to the electronics assembly 236, as explained further below. Some or all of the hoses 260A, 260B, and 260C and the cables 262-1 and 262-2 can be secured to the frame 232 with suitable fittings 260F (e.g., harnesses, clamps, tethers, or the like). By attaching components like the electric motor assemblies 234-1 and 234-2 to a frame 232 that has spaced apart crossbars 232C₁ and 232C₂ and legs 232L₁ and 232L₂, airflows can pass around, between, and/or through such components, which can facilitate cooling the electric motor assemblies 234-1 and 234-2 and also help to limit obstruction or interference with cooling airflows used to cool nearby objects like the heat exchanger assembly 57 (see FIG. 2).

In the illustrated embodiment, the electronics assembly 236 is a shared or common assembly that can control and power both the first and second electric motor assemblies 234-1 and 234-2, and which can be located remotely from the first and second electric motor assemblies 234-1 and 234-2 and the frame 232. That is, in the illustrated embodiment, the electronics assembly 236 is not directly attached to the frame 232 or otherwise supported or carried by the frame 232, but rather is supported at a different, remote mounting location, such as at a different location within a motor compartment of the vehicle 51. Although in further embodiments the electronics assembly 236 could be supported on the frame 232 or otherwise be located in close proximity to the electric motor assemblies 234-1 and 234-2.

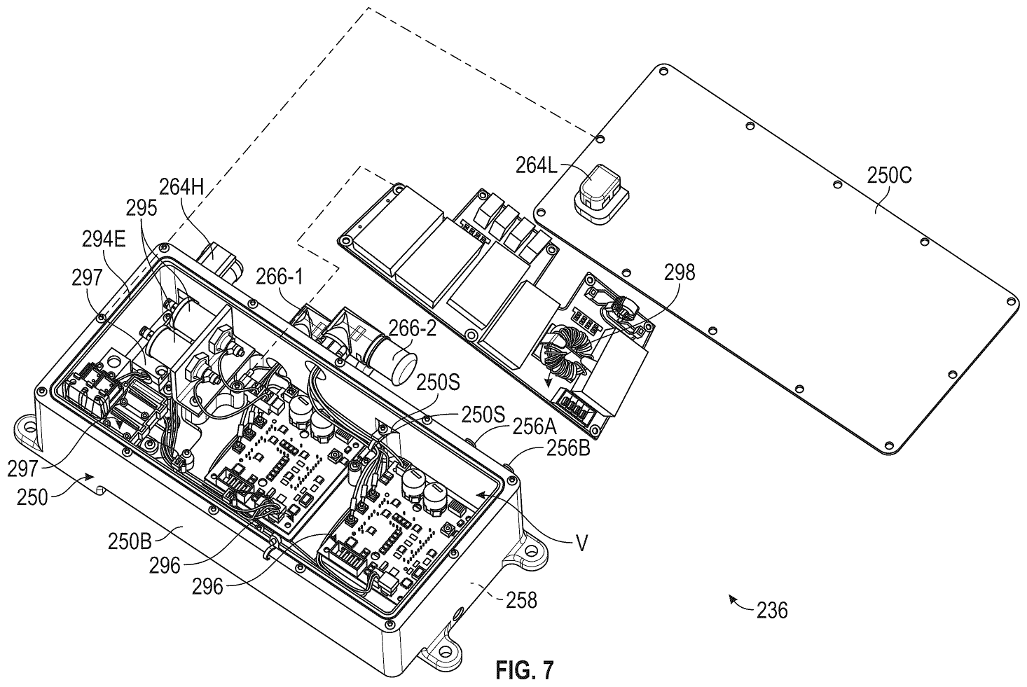

The electronics assembly 236 can include an enclosure 250 with a base 250B and a cover 250C, inlet and outlet ports 256A and 256B fluidically connected to a liquid cooling channel 258, a high voltage input connector 264H, a low voltage connector 264L, and output electrical connectors 266-1 and 266-2. Internal components of the electronics assembly 236 are discussed later in the present disclosure. As shown (see also FIG. 7), the base 250B is made of a metallic material, such as aluminum, and has multiple external walls that define an interior volume V with an opening that can be closed by the cover 250C, which is removable to allow access to components within the interior volume (and which can be made of a metallic material). As explained further elsewhere in this disclosure, at least the base 250B of the enclosure can be electrically grounded, which can allow other components to be electrically grounded via an electrical connection to a wall of the base 250B. In the illustrated embodiment, the inlet and outlet ports 256A and 256B are located adjacent one another on a side wall of the base 250B along with the high voltage input connector 264H and the output electrical connectors 266-1 and 266-2, which can be staggered relative to each other, while the low voltage connector 264L can be located on the cover 250C. Additional details of the electronics assembly 236 are explained below.

The cables 262-1 and 262-2 for the electric motor assemblies 234-1 and 234-2 can each be connected to one of the output electrical connectors 266-1 and 266-2 of the electronics assembly 236, and thereby create electrical connections between the electronics assembly 236 and both of the electric motor assemblies 234-1 and 234-2. In this way the cables 262-1 and 262-2 facilitate having the electronics assembly 236 located remotely from the electric motor assemblies 234-1 and 234-2. Suitable electrical cables (not shown) can be connected to the high voltage input connector 264H and the low voltage connector 264L in order to provide power input to electronics within the interior volume of the electronics enclosure 250 and further provide electrical signals for communications, typically via the low voltage connector 264L. The electronics within the interior volume of the electronics enclosure 250 can in turn power and communicate with the electric motor assemblies 234-1 and 234-2 via the output electrical connectors 266-1 and 266-2. In some embodiments, the output electrical connectors 266-1 and 266-2 and/or the low voltage connector 264L can be combined connectors for both electrical power and electrical signal transmission, as explained further later in the present disclosure. Further, electrical grounding can be provided to the electronics assembly 236 through the high voltage input connector 264H and an associated input cable, for example.

The cables 262-1 and 262-2 that electrically connect the electronics assembly 236 to the electric motor assemblies 234-1 and 234-2 can carry both the phase wires to power each electric motor and signal wires to monitor the temperature of associated stator(s). Grounding of the electric motor assemblies 234-1 and 234-2 can also be provided through these same cables 262-1 and 262-2, as discussed further below. The phase wires can carry high voltage current (e.g., 600 VDC or more, such as approximately 900 VDC), whereas the signal wire(s) can operate at significantly lower voltages (e.g., significantly below 500 VDC). Each cable 262-1 and 262-2 can have individual shielded twisted pair wires in addition to an outer shield for the entire cable 262-1 and 262-2. The outer shield of each cable 262-1 and 262-2 can be connected to a cable gland and electrical connector with a 360° attachment. This facilitates an electromagnetic compatibility (EMC) strategy to help meet radiated emissions objectives and requirements.

The liquid cooling channel 258 can extend through at least one wall of the base 250B or the enclosure 250 (e.g., an external wall), and be separated from the interior volume V. In some embodiments, the liquid cooling channel 258 can be located in a bottom external wall of the base 250B opposite the cover 250C and associated opening, although other arrangements are possible in further embodiments. A liquid coolant present in the liquid cooling channel 258 can conductively absorb thermal energy from the electronics assembly 236, such as waste heat from power electronics located within the interior volume V, the heated liquid coolant can flow or be pumped along a liquid flow path in the liquid cooling circuit C to be dissipated, for instance at the radiator 57B (see FIG. 2). The liquid cooling channel 258 is in fluid communication with the inlet and outlet ports 256A and 256B, which can fluidically connect the liquid cooling channel 258 to the liquid cooling circuit C with suitable hoses or the like. As shown in the illustrated embodiment of FIG. 4E, the liquid cooling channel 258 can be made by drilling a number of linear bores into the base 250B and then plugging those segments other than those connected directly to the inlet and outlet ports 256A and 256B. For instance, the illustrated embodiment includes a pair of physically parallel elongate segments drilled from opposite ends of the base 250B, with region of overlap in a middle part of the base 250B, plus three additional physically parallel segments drilled from the same side of the base 250B at approximately 90° to the pair of elongate segments with two of the additional segments intersecting only one of the pair of elongate segments and the third additional segment intersecting both of the elongate segments. In the illustrated embodiment, a portion of the liquid cooling channel 258 forms a dead-end segment, but otherwise creates a liquid cooling path that fluidically connects the inlet and the outlet ports 256A and 256B while also extending to portions of the base 250B adjacent to where waste heat is expected to be generated by electrical components contained in the interior volume during operation. Other aspects of the liquid cooling circuit C and its relationship to the electric motor assemblies 234-1 and 234-2 and/or the electronics assembly 236 are discussed later in the present disclosure. Moreover, it should be noted that the illustrated configuration of the liquid cooling channel 258 is shown merely by way of example and not limitation. Other pathway shapes are possible in further embodiments, and internal turbulators or surface area enhancements can be used as desired in further embodiments. Moreover, casting, etching, or other processes other than drilling can be utilized to create the liquid cooling channel 258 in some embodiments, which may allow for more complex pathway shapes, the use of turbulators, etc. Furthermore, it is possible for the liquid flow path through the liquid cooling channel 258 to be reversed, that is, in some embodiments, the connection of hoses (e.g., the hoses 260A and 260C) to the liquid cooling channel 258 are effectively interchangeable and can be connected in any manner desired to allow the liquid coolant to flow in either direction through the liquid cooling channel 258 depending on the manner in which input and output lines are connected at any given time.

During operation, the electronics assembly 236 can drive and control energization of the first and second electric motor assemblies 234-1 and 234-2. An external controller, such as a vehicle controller on-board the vehicle 51, can in turn send signals that control the electronics assembly 236 or are otherwise utilized by the electronics assembly 236 for operation. For instance, an external controller (not shown) can provide a cooling demand signal and/or an enable/disable signal to the electronics assembly 236, which the electronics assembly 236 uses to selectively energize one or both of the electric motor assemblies 234-1 and 234-2 to rotate one or both of the fans 238-1 and 238-2 at desired speed(s), etc., and such control can occur on a fully variable basis.

The first and second fans 238-1 and 238-2 are operatively connected to the first and second electric motor assemblies 234-1 and 234-2, such that the electric motor assemblies 234-1 and 234-2 can selectively rotate the fans 238-1 and 238-2 as governed, at least in part, by the electronics assembly 236. The first and second guards 240-1 and 240-2 can partly or completely enclose the fans 238-1 and 238-2. Because the fans 238-1 and 238-2 might begin rotating unexpectedly, even under conditions when the system 230 is in a vehicle that is not being driven or otherwise moving, the guards 240-1 and 240-2 help prevent nearby persons from having fingers or other appendages too close to the fans 238-1 and 238-2. The guards 240-1 and 240-2 can be supported directly or indirectly by the frame 232. In the illustrated embodiment, the guards 240-1 and 240-2 are only at a rear side of the fans 238-1 and 238-2 but guard covers (not shown) can further be provided at the front of the fans 238-1 and 238-2 to fully enclose them.

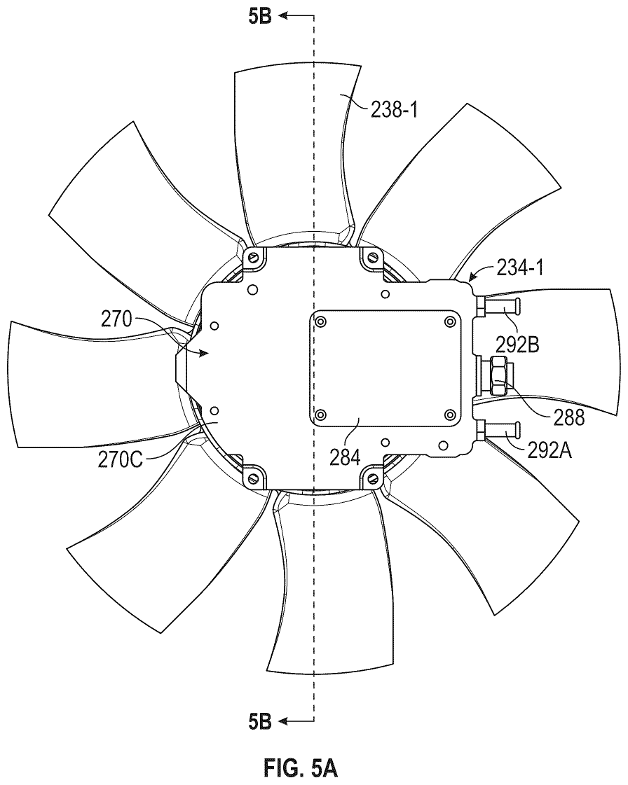

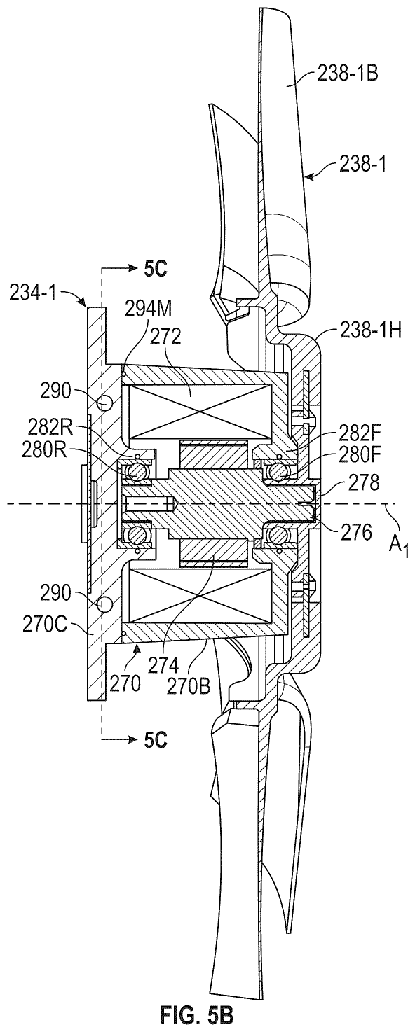

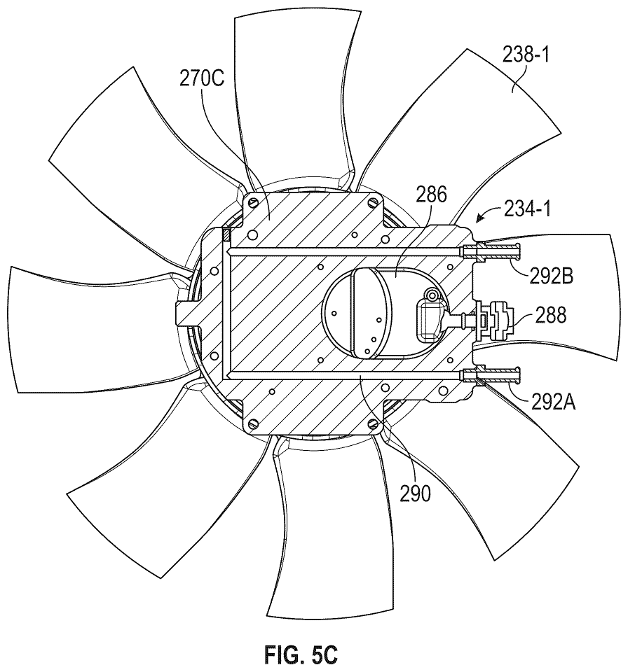

FIG. 5A is a rear elevation view of the electric motor assembly 234-1 and the fan 238-1, shown in isolation, while FIG. 5B is a sectional view taken along line 5B-5B of FIG. 5A and FIG. 5C is a sectional view taken along line 5C-5C of FIG. 5B. While only the first high voltage electric motor assembly 234-1 is shown in FIGS. 5A-5C, the second high voltage electric motor assembly 234-1 can be configured identically to the first high voltage electric motor assembly 234-1 in some embodiments. The electric motor assembly 234-1 can be synonymously referred to as a fan motor.

The electric motor assembly 234-1 includes a housing 270, a stator 272, and a rotor 274 with a rotor shaft 276. An optional fan adapter 278 can also be provided, to facilitate attachment of the fan 238-1 to the electric motor assembly 234-1. The rotor shaft 276 carries components of the rotor 274 on bearings 280F and 280R, allowing the rotor 274 and the rotor shaft 276 to rotate relative to the stator 272 and the housing 270. Moreover, a temperature sensor (not shown) and/or other sensor(s) can be incorporated into the electric motor assembly 234-1, such as in or near the stator 272. The electric motor assembly 234-1, specifically the rotor 274 and the stator 272, can have a permanent magnet synchronous motor configuration such as a brushless DC (BLDC) design. More specifically, the electric motor assembly 234-1 can be a three phase BLDC design in some embodiments. The stator 272 and the rotor 274 can be procured as a set, using commercially-available components. For instance, in the illustrated embodiment, the stator 272 includes multiple windings (shown only schematically in FIG. 5B) and the rotor 274 includes a plurality of permanent magnets carried on the rotor shaft 276. The housing 270 has certain special features unique to high-voltage and/or vehicular applications.

In the illustrated embodiment, the stator 272 has three windings out of phase by 120°. The windings of the stator 272 can be situated around steel flux elements to direct a magnetic field during operation. The stator 272 can be potted in a hardened resin to protect it from environmental conditions such as temperature, moisture, and vibration. A sensor, such as a temperature sensor, can also be potted with the stator 272. The stator 272 is generally situated wholly, or at least partially, inside an interior volume of the housing 270.

The rotor 274 of the illustrated embodiment includes the rotor shaft 276 and further includes a number of permanent magnets situated at or near an outer diameter. The permanent magnets are located in the area of the rotor shaft 276 that sits directly radially inside of the stator 272 in the illustrated embodiment. The rotor and associated permanent magnets are also located wholly or at least partially inside the housing 270. The rotor shaft 276 can be longer than the stator 272 and can extend far enough beyond the permanent magnets at each end to place at least one of the bearings 280F and/or 280R between rotor shaft 276 of the rotor 274 and the housing 270. One end of the rotor shaft 276 can extend sufficiently beyond the nearest bearing (e.g., the front bearing 280F) to permit the direct or indirect attachment of the fan 238-1 outside the housing 270 and, in that sense, at least one end of the rotor shaft 276 can extend through and outside of the housing 270. The rotor shaft 276 is rotatable relative to the stator 272 and the housing 270, and defines the axis of rotation A₁ of the rotor 274 and the fan 238-1.

In some embodiments, the fan adapter 278 (also called a fan mount) is secured to the rotor shaft 276 and the fan 238-1 is attached to the fan adapter 278, such that the fan 238-1 is indirectly secured to the rotor shaft 276 and rotates with the rotor 274 when the electric motor assembly 234-1 generates a torque output. The fan adapter 278 can be attached at or near one end of the rotor shaft 276, such as at a front end as shown in the illustrated embodiment, in a rotationally fixed manner. When utilized, the fan adapter 278 provides an externally exposed fan mounting location while the permanent magnets of the rotor 274 and the windings of the stator 272 remain enclosed within the housing 270. As shown in FIG. 5B, for example, the fan adapter 278 can be located at or near an end of the rotor shaft 276 that extends outside the body 270B of the housing 270 (e.g., a front end opposite the cover 270C) and, with respect to the nearest bearing 280F, can also be located opposite the permanent magnets of the rotor 274. In embodiments without a fan adapter, the fan 238-1 can be connected directly to the rotor shaft 276 or operatively engaged with the rotor shaft 276 by other suitable direct or indirect mechanical connections.

In the illustrated embodiment, the fan 238-1 can include a cup-like center section or hub 238-1H, which can at least partially wrap around the housing 270 of the electric motor assembly 234-1 and which can place a significant portion of the electric motor assembly 234-1 within the axial space of the fan 238-1. Further, the cup-like shape of the hub 238-1H allows blades 238-1B of the fan 238-1 to be positioned axially rearward, such as with leading edges of the blades 238-1B positioned no further axially forward than the front end of the rotor shaft 276 and/or where the fan 238-1 is attached to the fan adapter 278, such as being axially rearward of the fan adapter 278 and/or the front end of the rotor shaft 276. Such a wrap-around configuration helps reduce an axial length of the overall high voltage electric fan cooling system 230. Additionally, the fan 238-1 can be configured to allow stacking when not installed in the system 230, to help reduce space occupied when in storage. During operation, the fan 238-1 is rotationally driven by the rotor shaft 276 when the electric motor assembly 234-1 produces a torque output.

The housing 270 of the electric motor assembly 234-1 can include at least a body (or base) 270B, and, as shown in the illustrated embodiment, can further include a cover 270C (though in alternate embodiments an opening in a housing body of a motor assembly can be covered by a component shared with an enclosure for an electronics assembly, as discussed further below). The body 270B of the housing 270 can provide an interior volume in which the stator 272 and the rotor 274 are positioned, at least partially. In the illustrated embodiment, the body 270B can have a cup-like shape with a rear-facing opening. A seal can be provided between the body 270B and the cover 270C, and motor enclosure provided in part by the housing 270 can be liquid-tight to seal against liquid incursion. The body 270B is the portion that sits generally around the stator 272 and the cover 270C closes the body 270B at an end (e.g., rear end) of the electric motor assembly 234-1. The cover 270C can be secured to the body 270B with suitable fasteners, and, in the illustrated embodiment, the cover 270C includes one or more flanges to allow the housing 270 to be secured to the frame 232 with suitable fasteners. In the illustrated embodiment, the bearing 280R rotatably supports the rotor shaft 276 of the rotor 274 on the cover 270C (or on a shared component that serves as the motor housing cover in alternative embodiments) and the bearing 280F rotatably supports the rotor shaft 276 of the rotor 274 on the body 270B of the housing 270. Suitable bearing pilots 282F and 282R can be provided on the body 270B and the cover 270C, respectively, to accept and help secure the respective bearings 280F and 280R. At least in embodiments in which the electric motor assembly 234-1 and the electronics assembly 236-1 are separated, the cover 270C can further include a cap 284, which can be removable, that allows access to a cavity 286 for terminating motor winding wires (see FIGS. 5A and 5C). In this sense, the cavity 286 can be open to the interior volume of the body 270B to permit electrical connections with suitable wires. An electrical connector 288 can further be provided on the housing 270, such as on the cover 270C, that can be electrically connected to wires via the cavity 286, and which is engageable with the cable 262-1. The body 270B and the cover 270C can each be made of aluminum, which is lightweight and has very good heat conductivity.

The housing 270 (e.g., the cover 270C) can include a provision for cooling. As shown in FIGS. 5B and 5C, the housing 270 can also include a liquid cooling channel 290 and inlet and outlet ports 292A and 292B that are fluidically connected to the liquid cooling channel 290. The inlet and outlet ports 292A and 292B can be fluidically connected to the hoses (e.g., the hoses 260A and 260C) to fluidically connect the liquid cooling channel 290 to the liquid cooling circuit C. As noted above, either of the inlet and outlet ports 292A and 292B can serve as the inlet or outlet, respectively, depending on how the hoses connect the liquid cooling channel to the rest of the liquid cooling circuit C, such that the direction of flow of the liquid cooling path through the liquid cooling channel 258 is effectively reversible. The liquid cooling channel 290 can pass through one or more portions of the housing 270, such as through parts of the cover 270C, in close proximity to heat-generating components, such as adjacent to and axially rearward of the stator 272, such that liquid coolant present in the liquid cooling channel 290 flow along a cooling path and can absorb thermal energy from components of the electric motor assembly 234-1, with the heated liquid coolant then carried away by the liquid cooling circuit C. Coolant flowing through the liquid cooling channel 290 can conductively absorb heat from the electric motor assembly 234-1 and carry the absorbed thermal energy out of the electric motor assembly 234-1 to a heat exchanger (see, e.g., radiator 57B in the heat exchanger assembly 57 of FIG. 2) to provide convective heat dissipation in a closed loop. The liquid coolant can be circulated through the liquid cooling channel 290 by a suitable pump (see, e.g., circulating pump 30P in FIG. 2). The liquid cooling channel 290 can pass along one or more sides of the cavity 286, without intersecting the cavity 286 or any other electrical connection openings, such as surrounding the cavity 286 on three sides. More particularly, the illustrated embodiment provides liquid cooling via the liquid cooling channel 290 at or near one axial end of the electric motor assembly 234-1, adjacent to axial ends of both the stator 272 and the rotor 274 at one side of the electric motor assembly 234-1. In the illustrated embodiment, the liquid cooling channel 290 turns a liquid cooling path by at least approximately 180° and has a generally U-shape.

The liquid cooling channel 290 can be fabricated, for example, by connecting a series of holes (e.g., by drilling or casting) to create a pathway through the cover 270C (with suitable plugs to create a desired fluid circuit). In the illustrated embodiment, three holes (with suitable end plugs) are provided in the cover in generally a U-shape that surrounds the wire termination cavity 286 on three sides, though other shapes and arrangements are possible in further embodiments.

It should be noted that the shape of the liquid cooling channel 290 is shown merely by way of example and not limitation. Various alternative configurations are possible in further embodiments, such as with more complex serpentine cooling paths. For instance, different numbers and arrangements of passages can be used in the liquid cooling channel 290, and multiple separate cooling channels could also be provided in alternate embodiments. Furthermore, serpentine or other more complexly-shaped passages can be used, which could be created by casting, machining, or other suitable manufacturing processes. Moreover, pins, strips, or other structures can be incorporated in or with the liquid cooling channel 290 to increase the amount of surface area available to conductively transfer thermal energy to the coolant, and/or to generate turbulence to enhance convective cooling effects. Additionally, the liquid cooling channel 290 could pass through the body 270B in further embodiments.

The housing 270 serves many functions. First, the housing 270 provides a mounting structure for securing the electric motor assembly 234-1 to a structural element (such as the frame 232). Second, the housing 270 locates the stator 272 relative to the rotor 274. The housing 270 also conducts heat away from interior components of the electric motor assembly 234-1, such as the stator 272.

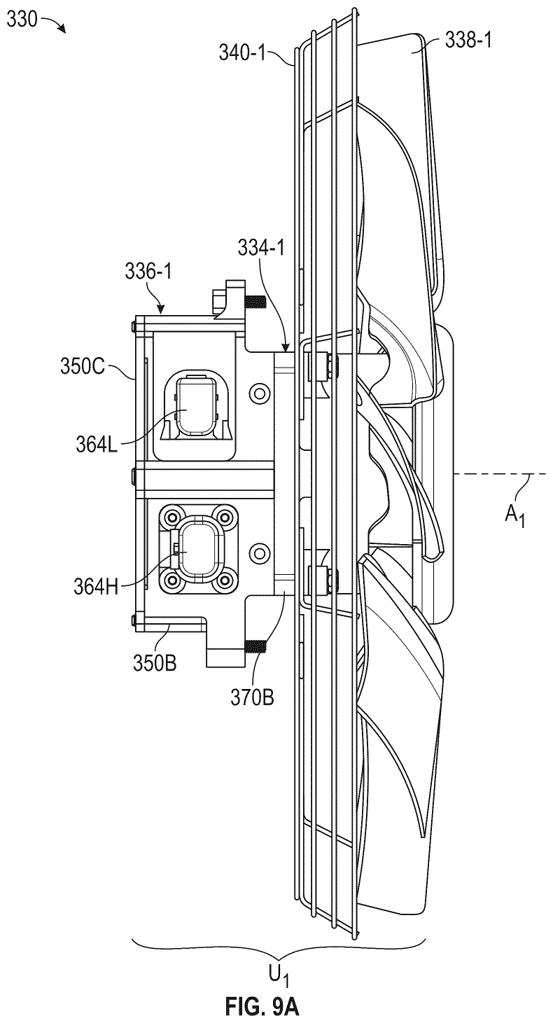

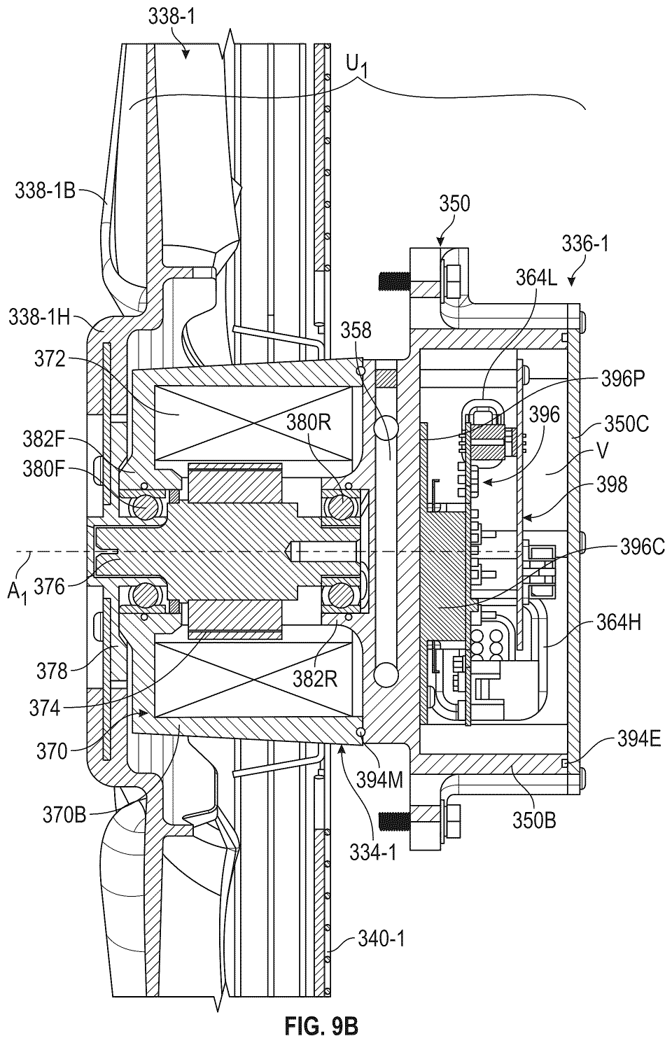

While the embodiment of the electric motor assembly 234-1 shown in FIGS. 5A-5C is configured for use with a remotely-located electronics assembly 236-1, the basic components of the electric motor assembly 234-1 such as the stator 272 and the rotor 274 can be the same or very similar in alternative embodiments (e.g., embodiments with a combined electronics assembly and electric motor assembly unit), as discussed further elsewhere in the present disclosure. In alternative embodiments in which an enclosure for the electronics assembly is combined with the motor assembly as a common unit, the motor housing cover 270C can be omitted and part of the electronics assembly enclosure box can be further utilized in a shared manner to cover an opening to an interior volume of the body of the motor housing (see, e.g., FIGS. 3A, 3B, 9A, and 9B). Such alternative embodiments are discussed further below. Though it is noted here that the function of covering an opening in the electric motor housing 270 can be provided by either the dedicated cover 270C or, alternatively, a shared component that serves both as the motor housing cover and as a component of a different assembly (e.g., as an enclosure for the electronics assembly), as discussed elsewhere.

In multi-fan embodiments, such as with the electric cooling fan system 230 having a dual fan configuration, the liquid cooling circuit C can have different configurations to provide liquid coolant to the fan motors (e.g., the electric motor assemblies 234-1 and 234-2) and/or the electronics assembly or assemblies (e.g., the electronics assembly 236) either in series or parallel, and combinations of series and parallel portions.

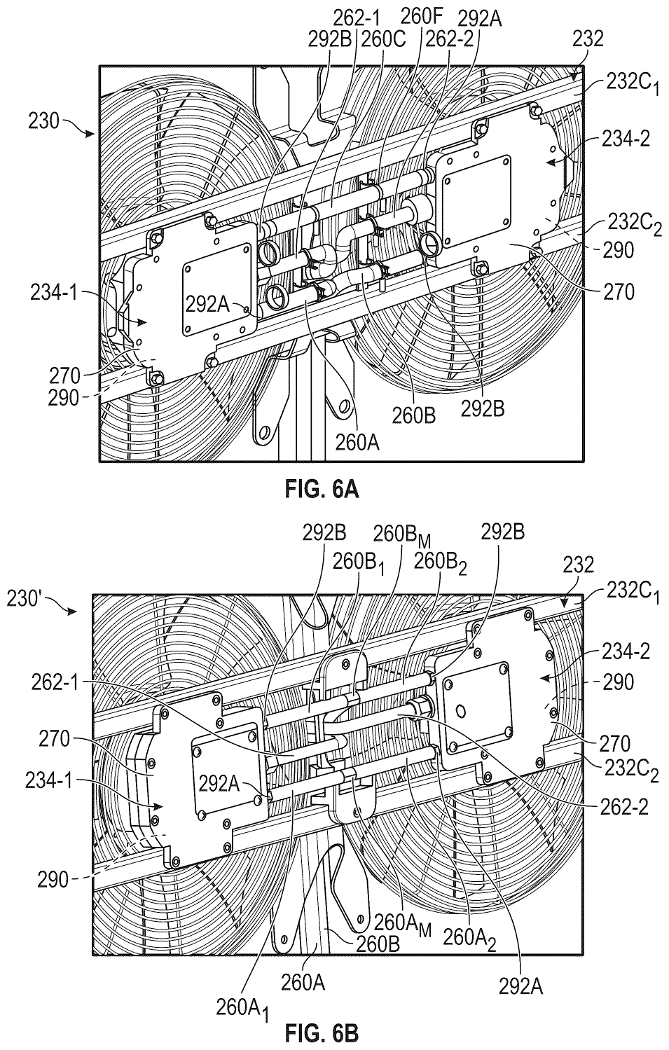

FIG. 6A is a rear perspective view of a portion of an embodiment of the electric cooling fan system 230 (utilizing the remotely-located electronics assembly 236, which is not visible in FIG. 6A) having a portion of the liquid cooling circuit C at the electric motor assemblies 234-1 and 234-2 configured in flow series. As shown in the illustrated embodiment of FIG. 6A, an inlet line (e.g., a fluid pathway through the hose 260A) is connected to a coolant inlet port 292A of the housing 270 of the first electric motor assembly 234-1, a series connection line (e.g., a fluid pathway through the hose 260C) connects a coolant outlet port 292B of the housing 270 of the first electric motor assembly 234-1 to a coolant inlet port 292A on the second electric motor assembly 234-2, and a coolant outline line (e.g., a fluid pathway through the hose 260B) is connected to a coolant outlet port 292B of the housing 270 of the second electric motor assembly 234-2. The inlet and outlet lines (e.g., the hoses 260A and 260B) connect to the liquid cooling circuit C, and thus can be connected in fluid communication with a heat exchanger (e.g., the radiator 57B) and circulating pump (e.g., the circulating pump 30P) that is not visible in FIG. 6A (but see, e.g., FIG. 2).

During operation of the series-connected embodiment of FIG. 6A (and also shown in the embodiment of FIGS. 4A and 4B), relatively cool liquid coolant is delivered to the coolant inlet port 292A of the first electric motor assembly 234-1, where the liquid coolant passes through the internal liquid cooling channel 290 of the first electric motor assembly 234-1 and thermal energy is transferred to the liquid coolant from the first electric motor assembly 234-1. The now slightly hotter liquid coolant is then delivered to the coolant inlet port 292A of the second electric motor assembly 234-2 via the series connection line (e.g., the hose 260C), where the liquid coolant passes through the internal cooling channel 290 of the second electric motor assembly 234-2 and additional thermal energy is transferred to the liquid coolant from the second electric motor assembly 234-2. In this way a liquid cooling path that is part of the liquid cooling circuit C can pass adjacent to both a stator 272 of the first electric motor assembly 234-1 and another stator 272 of the second electric motor assembly 234-2, which in the illustrated embodiment occurs essentially sequentially in a flow series relationship. In further embodiments, more than two electric motor assemblies could be fluidically connected in series in a similar manner. In a series configuration, the liquid cooling circuit C provides less cooling to the second (or downstream) electric motor assembly 234-2. However, assembly and fabrication can be simplified, in part because manifolds or the like are not required to connect the liquid coolant lines (e.g., the hoses 260A, 260B, etc.) at or near the electric motor assemblies 234-1 and 234-2. In order to provide suitable bends liquid coolant lines with reduced risk of kinking, the hoses 260A and 260B used to form at least some of those lines can be hardened or semi-hardened in a desired three-dimensional shape (for instance, with forced curvatures). For example, it is possible to vulcanize rubber-based hoses into desired shaped to provide a stable three-dimensional hose shape for at least the hoses 260A, 260B. Also, hoses 260A, 260B, 260B used to form the at least some of the lines of the liquid cooling circuit C can be guided and/or secured to the frame 232 with suitable fittings 260F.

FIG. 6B is a rear perspective view of a portion of an alternative embodiment of an electric fan system 230′ (utilizing a remotely-located electronics assembly 236, which is not visible in FIG. 6B) having a portion of the liquid cooling circuit C at the electric motor assemblies 234-1 and 234-2 configured fluidically in parallel. The electric fan system 230′ can generally include the same components and operate in the same manner as the electric cooling fan system 230 except as described here with regard to a parallel liquid flow path of the liquid cooling circuit C through the first and second electric motor assemblies 234-1 and 234-2. As shown in the illustrated embodiment of FIG. 6B, an inlet main or trunk line (e.g., the hose 260A) is connected to an inlet manifold 260A (e.g., a T-shaped fitting or other flow splitter) that in turn is connected to first and second inlet line branches (e.g., hose branches 260A₁ and 260A₂). The inlet line branches connect to respective coolant inlet ports 292A on the first and second electric motor assemblies 234-1 and 234-2. First and second outline line branches (e.g., hoses 260B₁ and 260B₂) connect to respective fluid outlet ports 292B on the first and second electric motor assemblies 234-1 and 234-2, and in turn to an outline line manifold 260B_{M} (e.g., a T-shaped fitting or other flow combiner) that further connects to an outlet main or trunk line (e.g., the hose 260B). The inlet and outlet main (or trunk) lines (e.g., the hoses 260A and 260B) connect to the liquid cooling circuit C, and thus can be connected in fluid communication to a heat exchanger (e.g., the radiator 57B) and circulating pump (e.g., the circulating pump 30P) that is not visible in FIG. 6B (but see, e.g., FIG. 2). During operation, relatively cool liquid coolant is delivered to the first and second electric motor assemblies 234-1 and 234-2 in parallel, where different discrete volumes of the liquid coolant pass through the internal liquid cooling channels 290 of the separate first and second electric motor assemblies 234-1 and 234-2 concurrently. In this way a liquid cooling path that is part of the liquid cooling circuit C can pass adjacent to both a stator 272 of the first electric motor assembly 234-1 and another stator 272 of the second electric motor assembly 234-2, which in the illustrated embodiment occurs through fluidically parallel branches of that liquid cooling path. The heated liquid coolant is then combined by the manifold 260B_{M} for return back to the heat exchanger (e.g., the radiator 57B). In a fluidically parallel configuration, the liquid cooling circuit C provides substantially equal cooling to each of the electric motor assemblies 234-1 and 234-2. Moreover, the use of manifolds 206A_{M} and 260B_{M} or the like can allow liquid coolant line hoses 260A, 260A₁, 260A₂, 260B, 260B₁, and 260B₂ to extend in a more linear manner, with the manifolds and the like providing redirection of fluid flow to achieve desired coolant line routing.

In still further embodiments with more than two fans and more than two electric motor assemblies, it is possible to utilize combinations of series and parallel liquid cooling paths through various portions of the liquid cooling circuit C, such as to have liquid cooling paths through some electric motor assemblies configured in series while liquid cooling paths through other electric motor assemblies are configured in parallel. Furthermore, the liquid cooling path through the liquid cooling channel 258 of the electronics assembly 236 can be fluidically connected to other parts of the liquid cooling circuit C that include the liquid cooling path through the first and second electric motor assemblies 234-1 and 234-2 in either series or parallel, regardless of whether the liquid cooling path through the first and second electric motor assemblies 234-1 and 234-2 is arranged in series (as shown in FIG. 6A) or in parallel (as shown in FIG. 6B).

Use of liquid cooling, in general, helps protect the components of the electric motor assemblies 234-1 and 234-2, particularly the windings of the stators 272, from thermal damage and degradation. For example, conventional diesel internal combustion engine compartments typically have a 100-110° C. operating range, and the present liquid cooling circuit C can similarly allow components of electric cooling fan system 230 to operate at no more than a 100-110° C. operating range, or, alternatively, at a lower thermal operating range, such as approximately 85° C. or less. Additionally, it has been found that electric fan motor and overall electric cooling fan system 230 efficiency (in terms of torque output) is increased through such liquid cooling of the electric motor assemblies 234-1 and 234-2. For example, testing has shown that initial estimates of approximately 6.2 Nm motor torque outputs were able to be unexpectedly increased to approximately 10.6 Nm as a result of use of the liquid cooling circuit C. Such benefits are realized when the system 230 operates using high voltages.

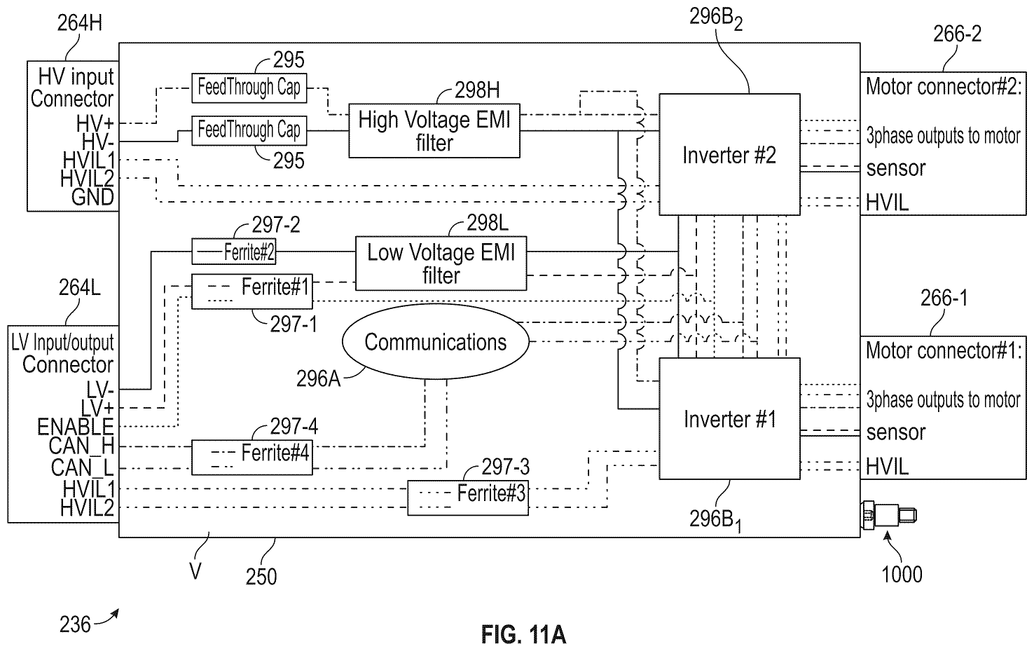

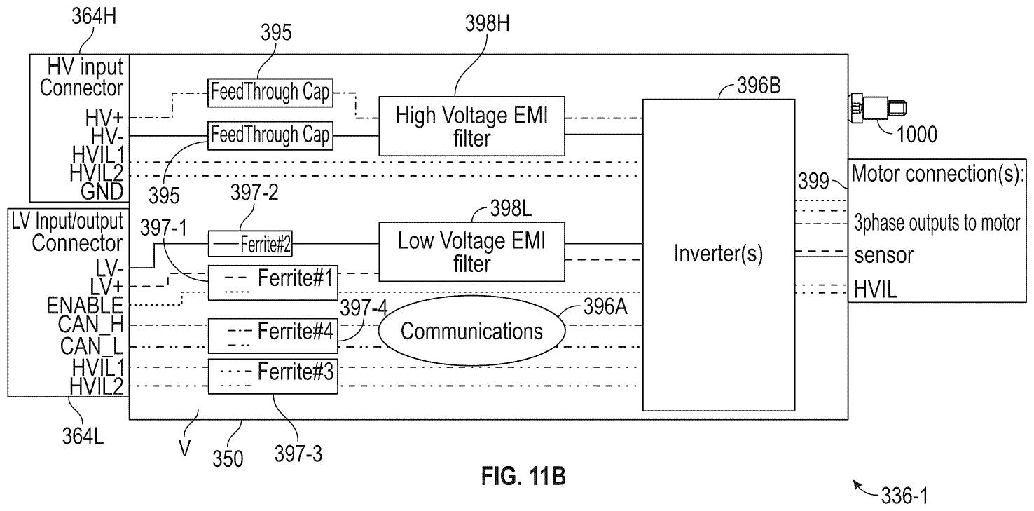

FIG. 7 is an exploded perspective view of the electronics assembly 336, shown in isolation. As shown the base 250B of the enclosure 250 provides the interior volume V with an opening that can be covered by the cover 250C, with a seal 294E (e.g., an O-ring type seal) positioned between them when fully assembled. Standoffs 250S can protrude into the interior volume V from the base 250B to facilitate attachment of circuit boards and/or other electrical components and to facilitate packaging a variety of high and low voltage components inside the enclosure 250 while helping to keep the electronics assembly 236 relative compact in overall size. The standoffs 250S can be made of a metallic material and electrically connected to a wall of the enclosure 250, and can optionally be integrally and monolithically formed with one or more walls of the enclosure 250 in some embodiments. As shown in the illustrated embodiment, the interior volume V of the enclosure 250 contains various electrical components, such as feedthrough capacitors 295, inverter and communications circuitry 296, one or more optional ferrites 297, electromagnetic interference (EMI) filter circuitry 298, and/or other components and associated wiring. The enclosure 250 and components in the interior volume V can be laid out in a manner to help reduce overall space required for components of the electronics assembly 236 as well as to accommodate wiring bends and other considerations. Other aspects of electrical components of the electronics assembly 236 are discussed further elsewhere in this disclosure (see, e.g., FIG. 11A and corresponding discussion).

In general, the enclosure 250 can contain and protect the inverter and communications circuitry 294 and other electrical equipment, such as to protect against environmental conditions that may be experienced in vehicular applications. In some embodiments, the interior volume V of the enclosure 250 can be sealed to be substantially liquid-tight, when the cover 250C is secured, while the various connectors 264H, 264L, 266-1 and 266-2 still allow for electricity and/or electrical signals to be transmitted in and/or out of the interior volume V of the enclosure 250. The seal 294E can be provided between the base 250B and the cover 250C to facilitate liquid-tight scaling. For example, in some embodiments, a hermetic seal is provided by the enclosure 250, while in alternative embodiments only partial sealing is provided. For example, in a further embodiment, the enclosure 250 can include a liquid-tight (e.g., waterproof), air-permeable membrane or valve, which could be located in an opening through the base 250B or the cover 250C. Such a membrane or valve can help account for thermal shock conditions, acceptable air ingress, and/or other conditions that do not pose a risk to components within the interior volume V of the enclosure 250 without compromising the liquid-tight seal. Pressure fluctuations due to thermal shocks might compromise a fully hermetic seal, whereas a semi-permeable membrane, for instance, can help equalize pressures between the interior volume V and exterior environment while still providing protection from potentially damaging liquids.

Low voltage (LV) and high voltage (HV) inputs into the enclosure 250 (and associated connectors 264L and 264H) can be configured with the HV input accepting DC power in a high voltage range of approximately 500-900 Volts DC or more (e.g., at approximately 900 VDC or approximately 850 VDC) and the LV input operating below that high voltage range (e.g., with power and/or electric signals significantly below 500 VDC).

The inverter and communications circuitry 296, and the EMI filter circuitry 298 can be implemented on one or more circuit boards. In the illustrated embodiment of FIG. 7, there are two discrete circuit boards for the inverter and communications circuitry 296, each one associated with one of the connectors 266-1 and 266-2 to further allow an operable electrical connection to one of the electric motor assemblies 234-1 and 234-2. Moreover, in the illustrated embodiment, the inverter and communications circuitry 296 combines high voltage inverter circuitry and low voltage communications circuitry on a single board. For instance, inverter circuitry of the inverter and communications circuitry 296 can include power electronics with high-speed electronic switching devices known as insulated-gate bipolar transistors (IGBTs) or Silicon carbide (SIC) metal-oxide-semiconductor field-effect transistors (MOSFETs). Also, as shown in the illustrated embodiment, the EMI filter circuitry 298 is implemented on a circuit board supported on the standoffs 250S so as to be stacked relative to the inverter and communications circuit boards, such as in a substantially parallel arrangement relative to at least one of the inverter and communications circuit boards. In further embodiments, the number of circuit boards, the use of printed circuit boards (PCBs), and the like can be adjusted as desired for particular applications. Moreover, although the electronics assembly 236 has been described as being shared by the electric motor assemblies 234-1 and 234-2, it is possible to have separate discrete circuit boards for some of all of the inverter and/or communications functions associated with each electric motor assembly 234-1 and 234-2, for instance, while such circuit boards are still commonly enclosed in the interior volume V of the same enclosure 250 and may still share common high and/or low voltage connectors 264L and/or 264H, EMI filter circuitry 298, etc. In other words, there may still be some dedicated electrical components within the electronics assembly 236 in some embodiments even if the overall electrics assembly 236 is considered shared.

The inverter and communications circuitry 296, and the inverter circuitry in particular, can be located adjacent to an external wall of the enclosure 250. In the illustrated embodiment, the inverter and communications circuitry 296 (and associated circuit board(s)) are positioned adjacent to a bottom wall of the base 250B of the enclosure 250 in close proximity to the liquid cooling channel 258. Such an arrangement allows for conductive heat transfer to liquid coolant flowable through the liquid cooling channel 258. Inverter circuitry switches high voltage current at a very high frequency. Because of the rapid switching, the inverter portion of the inverter and communications circuitry 296 has energy losses in the form of heat. As such, inverter circuitry is particularly prone to generating significant amounts of waste heat. A cold plate and/or thermal paste or a thermal pad can be positioned adjacent to the inverter and communications circuitry 296, in between the inverter and communications circuitry 296 and the liquid cooling channel 258 and an associated wall of the enclosure 250, to facilitate thermal energy transfer from the inverter and communications circuitry 296 to the liquid coolant present in the liquid cooling channel 258. Because the EMI filter circuitry 298 and/or other electrical components located in the interior volume V of the enclosure 250 tend to generate less waste heat than the inverter circuitry, such components can be arranged inside the interior volume V further away from the liquid cooling channel 258. In further embodiments, however, the liquid cooling channel 258 could extend through multiple walls of the enclosure 250 and/or multiple discrete cooling channels could be provided.

FIG. 8 is a rear perspective view of an alternate embodiment of a high voltage cooling fan system 330 with a dual-fan configuration. FIGS. 9A and 9B are side elevation and sectional views, respectively, of portions of the high voltage cooling fan system 330, shown in isolation, illustrating an embodiment of an electric motor assembly 334-1 and an electronics assembly 336-1 packaged together in a combined unit U₁. The electric cooling fan system 330 can include a frame 332, a plurality of electric motor assemblies 334-1 and 334-2, a plurality of electronics assemblies 336-1 and 336-2, a plurality of fans 338-1 and 338-2 (each having blades and a hub), and a plurality of guards 340-1 and 340-2. The respective electric motor assemblies 334-1 and 334-2 and electronics assemblies 336-1 and 336-2 can each be packaged and connected together as combined units U₁ and U₂.

The frame 332 of the illustrated embodiment includes crossbars 332C₁ and 332C₂ (which can also be referred to as main tubes in some embodiments), legs 332L₁ and 332L₂, and auxiliary legs 332_{A1} and 332_{A2}. The frame 332 can be at least partially made of hollow tubing, with certain modifications that make such bent tubing suitable for the conditions experienced in vehicular applications. As shown, the crossbars 332C₁ and 332C₂ can be generally linear and arranged horizontally, while the legs 332L₁ and 332L₂ and the auxiliary legs 332_{A1} and 332_{A2} can each have nonlinear shapes. The legs 332L₁ and 332L₂ are arranged and connected at or near the ends of the crossbars 332C₁ and 332C₂ while the auxiliary legs 332_{A1} and 332_{A2} are arranged and connected at middle portions of the crossbars 332C₁ and 332C₂ with each auxiliary leg 332_{A1} or 332_{A2} located directly adjacent to a corresponding one of the combined units U₁ or U₂. The crossbars 332C₁ and 332C₂ can have elongate shapes and considerable length to allow the electric motor assemblies 334-1 and 334-2 to be connected and arranged in a side-by-side configuration while still allowing the fans 338-1 and 338-2 to rotate without interference, such as in a side-by-side arrangement with the fans 338-1 and 338-2 having respective axes of rotation A₁ and A₂ (axis A₂ is not visible in the drawings) that can be substantially parallel to each other. Solid ends 332S can be provided at ends of each of the legs 332L₁ and 332L₂ and the auxiliary legs 332_{A1} and 332_{A2} to close the tubular portions of the frame 332 against liquid incursion. In the illustrated embodiment, the solid ends 332S are configured as plates with fastener openings 332F oriented at an angle (e.g., approximately) 90° to the adjacent tubular portion and with a sealed (e.g., welded or brazed) joint 332J between them. The combined units U1 and U2 can be mounted generally in between the crossbars 332C₁ and 332C₂ and also in between the legs 332L₁ and 332L₂ and/or the auxiliary legs 332_{A1} and 332_{A2}. In general, the frame 332 can function similar to the frame 232 as discussed above. Moreover, in some embodiments, the frame 332 can be fabricated by bending the legs 332L; and 332L₂ and the auxiliary legs 332_{A1} and 332_{A2} to desired shapes, then securing the crossbars 332C₁ and 332C₂ to the legs 332L₁ and 332L₂ and/or the auxiliary legs 332_{A1} and 332_{A2}, such as by welding or brazing or alternatively with mechanical attachments such as fasteners, clamps, or the like, and then, subsequently, the solid end portions 332S can be attached to the legs 332L₁ and 332L₂ and/or the auxiliary legs 332_{A1} and 332_{A2}.

In general, components of the electric motor assembly 334-1 and the electronics assembly 336-1 of the combined unit U₁ can be similar or identical to those of the electric motor assemblies 234-1 and 234-2 and the electronics assembly 236 described above, with reference numbers generally increased in value by one hundred, with certain exceptions as noted herein regarding integrations as the combined units U₁ and U₂. For instance, apart from omission of the cover 270C as described further later in the present disclosure, the electric motor assembly 334-1 can be identical or substantially similar to the electric motor assembly 234-1 described above, in some embodiments. However, unlike the system 230, which in the illustrated embodiment uses a single shared (and remotely located) electronics assembly 236 to control and drive multiple electric motor assemblies 234-1 and 234-2, the system 330 can utilize a separately, dedicated electronics assembly 336-1 and 336-2 for each corresponding electric motor assembly 334-1 and 334-2. Components of each of the combined units U₁ and U₂ can be similar or identical to each other, and in the illustrated embodiment the combined units U₁ and U₂ differ only with respect to the arrangement of certain electrical connectors and liquid cooling ports. Other aspects of electrical components of the electronics assemblies 336-1 and 336-2 are discussed further elsewhere in this disclosure (see, e.g., FIG. 11B and corresponding discussion).

As shown in the illustrated embodiment of FIGS. 8-9B, the electronics assembly 336-1 can include an enclosure 350 having a base 350B and a cover 350C, a liquid cooling channel 358, a low voltage electrical connector 364L, and a high voltage electrical connector 364H. Moreover, as shown in the illustrated embodiment, the electric motor assembly 334-1 can include a housing 370 with a body (or base) 370B, a stator 372, a rotor with a rotor shaft 376, an optional fan adapter 378, bearings 380F and 380R, and a bearing pilot 382F on the body 370B. Inlet and outlet ports (not shown) for the liquid cooling channel 358 can be provided to connect the liquid cooling channel 358 to the liquid cooling circuit C with suitable hoses 360A, 360B, and 360C. In the illustrated embodiment, liquid cooling paths through the combined units U₁ and U₂ are fluidically connected in series, although in alternate embodiments a fluidically parallel configuration can be used instead.

The electronics assembly 336-1 includes the enclosure 350, which in turn includes the base 350B formed by a plurality of walls and the removable cover 250C to allow access to electrical components located inside (it should be noted that FIG. 9B omits or simplifies various internal electronics assembly components). The enclosure 350 can be sealed, such as with a seal 394E (e.g., an O-ring type seal), to protect internal components from environmental conditions. As shown in FIGS. 9A and 9B, the electronics assembly 336-1, and specifically the enclosure 350, is connected to the housing 370 of the electric motor assembly 334-1, and more specifically on the body 370B. Instead of a separate motor assembly housing cover, which is effectively omitted in the illustrated embodiment and thus help reduce overall mass of the system 330, a shared portion of the base 350B of the enclosure 350 of the electronics assembly 336-1 also serves as a motor assembly cover when the combined unit U₁ is fully assembled. That is, the body 370B of the housing 370 of the electric motor assembly 334-1 can be connected to the base 350B of the enclosure 350 of the electronics assembly 336-1 to close an opening in the body 370B, and a seal 394M (e.g., an O-ring type seal) can be provided between the housing 370 and the enclosure 350 to provide a liquid-tight arrangement. In some embodiments, the interior volume V of the enclosure 350 is sealed against liquid inclusion although the sealing boundary can be located beyond the boundaries of the interior volume, such as due to scaling provided by the body 370B of the housing 270 of the electric motor assembly 334-1 (which can itself be liquid tight) as part of the combined unit U₁. The bearing pilot 382R can be carried by and protrude from the base 350B of the enclosure 350 of the electronics assembly 336-1, and can accept and support the bearing 380R that rotatably supports the rotor shaft 376 of the electric motor assembly 334-1 at or near an opposite end from the bearing 380F that is located at the bearing pilot 382F, which can be carried by or be a part of the body 370B of the housing 370 of the electric motor assembly 334-1. In the way, a front end of the rotor shaft 376 is rotatably supported by the housing 370 of the electric motor assembly 334-1 while a rear end of the rotor shaft 376 is rotatably supported on the enclosure 350 of the electronics assembly 336-1, which provides a degree of structural integration in the combined unit U while still being readily manufacturable and relatively easy to assemble.

Also, in the illustrated embodiment the liquid cooling channel 358 is positioned axially in between the stator 372 of the electric motor assembly 334-1 (and the rear end of the rotor shaft 376) and an interior volume V of the electronics assembly enclosure 350 where inverter and communications circuitry 396, EMI filter circuitry 398, and/or other electrical components can be located. Such liquid cooling channel(s) 358 can provide liquid cooling to the electric motor assembly 334-1 in a manner similar to the cooling channels that can be used with the dedicated electric motor assembly 234-1 or 234-2 as described above. Moreover, such liquid cooling channel(s) 358 can be positioned in or adjacent to both assemblies 334-1 and 336-1 in order to concurrently provide cooling to both components of the electronics assembly 336-1 and components of the electric motor assembly 334-1. Additional details of the liquid cooling channel 358 are discussed later in the present disclosure.

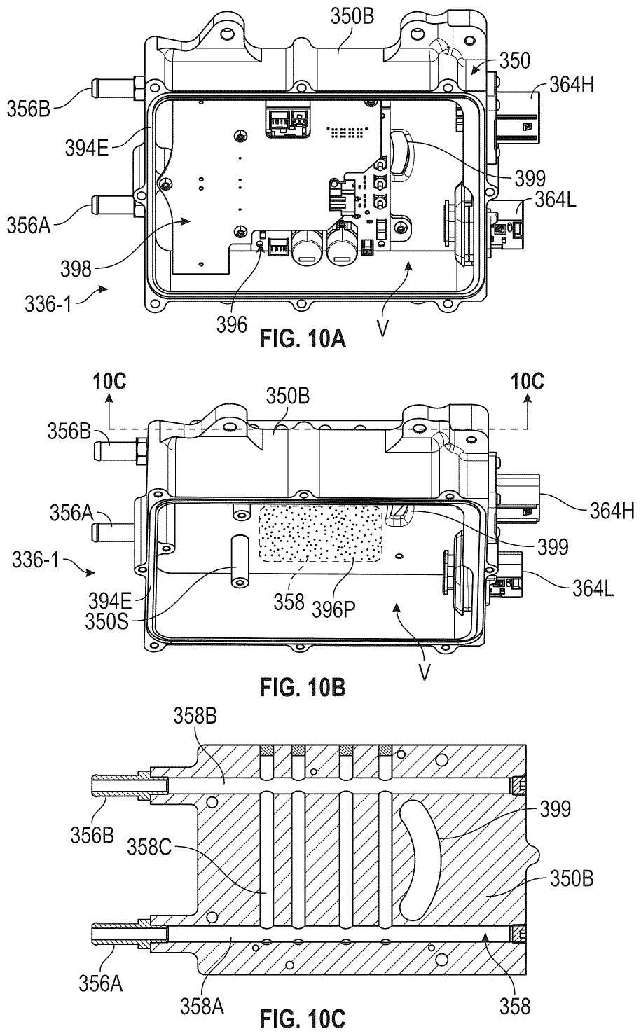

FIGS. 10A-10C illustrate portions of the electronics assembly 336-1 (shown with the cover 350C and various internal components omitted or simplified; for instance, FIG. 10B omits all internal electrical components). As shown in FIGS. 10A, the inverter and communications circuitry 396 can be provided on a circuit board positioned in the internal volume V adjacent to an external wall of the enclosure 350, such as in close proximity to a bottom wall through which at least a portion of the liquid cooling channel 358 extends. The EMI filter circuitry 398 can be provided on a circuit board that is carried on standoffs 350S, which can be made of a metallic material and electrically connected to a wall of the enclosure 350. In the illustrated embodiment the circuit board for the inverter and communications circuitry 396 and the circuit board for the EMI filter circuitry 398 are positioned in a stacked and substantially parallel arrangement within the interior volume V.

A wiring opening 399 can be provided in a wall of the enclosure 350 facing the electric motor assembly 334-1 (e.g., adjacent to the stator 372), and which further can be positioned within a sealing perimeter formed by the seal 394M, for instance. In the illustrated embodiment, the wiring opening 399 has an arcuate, slot shape, like a crescent, with cased and/or rounded edges. The liquid cooling channel 358 can at least partially surround that wiring opening 399 without intersecting the wiring opening 399. Because electrical wiring passing through the wiring opening 399 is protected from environmental conditions, it is not necessary to have exterior, environmentally-protected electrical cables (like the cables 262-1 and 262-2) or connectors (like the connectors 266-1 and 266-2) to connect the electric motor assembly 334-1 to the electronics assembly 336-1.

A cold plate 396C and/or a thermal material (e.g., a thermal paste or thermal pad) 396P can be positioned in between the liquid cooling channel 358 and electrical components in the interior volume V of the enclosure 350, such as the inverter and communications circuitry 396. In the illustrated embodiment (see FIGS. 9B and 10B), thermal paste 396P is applied directly to an interior side wall of the base 350B adjacent to the liquid cooling channel 358, and a circuit board for the inverter and communications circuitry 396 is mounted directly to the cold plate 396C, which can be made of a thermally conductive material such as aluminum, with the cold plate 396C positioned adjacent to the wall of the base 350B and the liquid cooling channel 358 with the thermal paste 396P in between. In this way, the cold plate 396C acts as a heat sink to help remove waste heat from the inverter and communications circuitry 396, while the thermal paste 396P helps promote good conductive thermal energy transfer from the cold plate 396C to the wall of the enclosure 350 and then to liquid coolant present in the liquid cooling channel 358.

As previously discussed, at least one liquid cooling channel 358 can be provided in the shared portion of the electronics assembly enclosure's base 350B. The liquid cooling channel 358 and an associated liquid flow path through the combined unit U₁ can be fluidically connected to the liquid cooling channel 358 and associated liquid flow paths through the combined unit U₂ in a liquid cooling circuit C of the system 330 either in series or in parallel, in a manner similar or identical to that discussed above with respect to FIGS. 6A and 6B. For instance, one or more walls of the base 350B of the enclosure 350 can contain an array of cross-drilled (and plugged) passage segments that create one or more liquid cooling channel(s) 358. In the illustrated embodiment of FIGS. 8-10C, the liquid cooling channel 358 turns a liquid cooling path extending through a portion of at least one wall of the enclosure 350 by approximately 180° or more. As shown in the illustrated embodiment of FIG. 10C, the liquid cooling channel 358 includes an array of passage segments including a pair of substantially (physically) parallel and linearly-extending primary segments 358A and 358B in fluid communications with the inlet and outlet ports 356A and 356B, respectively, and a plurality of linearly-extending connecting segments 358C, all located in a single wall of the enclosure 350. There are four connecting segments 358C in the illustrated embodiment, arranged substantially (physically) parallel to each other and each fluidically connected to both of the primary segments 358A and 358B, with the connecting segments 358C fluidically connected to the primary segments 358A and 358B in parallel and all located to one side of the wiring opening 399, and with the connecting segments 358C each arranged substantially physically parallel to each other and at approximately 90° to the primary segments 358A and 358B. Further, in the illustrated embodiment the primary segments 358A and 358B each have a dead end portion opposite the respective inlet or outlet port 356A or 356B. The primary segments 358A and 358B and the connecting segments 358C can each be made by drilling, casting, or other suitable manufacturing processes, and appropriate portions can be plugged or otherwise closed to define a desired liquid cooling path with the liquid cooling channel 358. As with the liquid cooling channel 258, flow of the liquid coolant through the liquid cooling channel 358 can be reversible in some embodiments, meaning that the system is insensitive with respect to which port 356A or 356B is used as an inlet and which as an outlet.

It is advantageous to mount an inverter circuit board of the inverter and communications circuitry 396, specifically its high-speed inverter switching portion (e.g., IGBTs or SiC MOSFETS), in close proximity to a liquid coolant, such as directly above liquid cooling channel(s) 358 in the wall(s) of the enclosure 350. This liquid cooling path through the liquid cooling channel 358 provides convective cooling via the liquid cooling circuit C as liquid coolant is circulated between the combined units U₁ and U₂ and a heat exchanger (e.g., the radiator 57B) by a suitable pump (e.g., the circulating pump 30P), as shown in FIG. 2. Cross-drilled linear passages can help simplify fabrication of the liquid cooling channel 358. However, the particular illustrated embodiment of the liquid cooling channel 358 is shown and described merely by way of example and not limitation. In further embodiments, other arrangements of cooling passages are possible. For instance, different numbers and arrangements of passages can be used, and multiple separate cooling channels could also be provided in alternate embodiments. Furthermore, non-linear (e.g., serpentine) passages can be used, which could be created by casting, machining, etching, and/or other suitable manufacturing processes. Moreover, pins, strips, or other structures can be incorporated to increase the amount of surface area available to conductively transfer thermal energy to the liquid coolant, and/or to generate turbulence to enhance convective cooling effects. In still further embodiments, the liquid cooling path through a given combined unit U₁ or U₂ could extend along multiple walls, such as through side walls of the base 350B of the enclosure 350 adjacent to the inverter circuit board. More complex liquid cooling paths described here with respect to the combined units U₁ and U₂ can also be utilized for liquid cooling channels in discrete and remotely-located electric motor assemblies and/or electronics assemblies, in some further embodiments.

Packaging the electronics assembly 336-1 with the electric motor assembly 334-1 in the combined unit U₁ has several advantages. First, there are fewer electrical connections and cables required in such a configuration. A single high voltage power line (e.g., a single power cable) enters the combined motor assembly/electronics assembly unit U₁. The wires that connect the windings of the stator 372 of the electric motor assembly 334-1 to the inverter and communications circuitry 396 of the electronics assembly 336-1 (e.g., passing through the wiring opening 399) can be completely contained within the combined unit U₁, which eliminates the need for expensive electrical cables and connectors to link remotely located housings and enclosures in areas that might be exposed to environmental conditions. Such cables and connectors for high voltage applications can be particularly costly due to the unique requirements and demands of high voltage industrial and vehicular applications. The liquid cooling channel 358, which can have a single inlet and single outlet formed by the inlet and outlet ports 356A and 356B in some embodiments, can be used to cool both the electronics assembly 336-1 and the electric motor assembly 334-1 concurrently. This eliminates extra liquid coolant plumbing required when they are separated and each device needs cooling lines to run independently. It is also important to note that extra cooling lines lead to higher pressure losses through the lines and potentially require a larger circulating pump, such that a combined unit can further allow use of a relatively smaller, lighter, and/or less powerful liquid coolant circulating pump (e.g., as the circulating pump 30P as shown in FIG. 2). However, the combined units U₁ and U₂ tend to cause the system 330 to have larger axial dimensions than the system 230.

More details of the electrical components of the electronics assemblies of the inventive high voltage cooling fan system will now be discussed. As already mentioned, the electric motor assemblies are each driven and controlled by an electronics assembly, which can be either dedicated to (and optionally combined with) a corresponding electric motor assembly or shared by multiple electric motor assemblies (and optionally located remotely from the electric motor assemblies). In general, the electronics assembly provides communication with the equipment being cooled by the high voltage electric fan system, such as by communicating with an on-board vehicle computer, communication with various sensor(s) within the high voltage cooling fan system, as well as provides a power electronics subsystem with an inverter to drive fan motor(s), provide electrical filtering functions, etc. The provision of both high voltage and low voltage electrical equipment together, packaged in a way that allows for protection against environmental conditions while also allowing for regulation of thermal operating conditions, control of EMI, and the like, presents a number of challenges that are addressed by embodiments of the presently disclosed high voltage cooling fan system.

FIG. 11A is a schematic illustration of electrical components of the electronics assembly 236. The same illustrated configuration could also be used for the electronics assembly 36 as well. As shown in the illustrated embodiment, the electronics assembly 236 includes the enclosure 250 that includes a wall (e.g., an external-facing wall) and that defines the interior volume V, the low voltage (LV) connector 264L, the high voltage (HV) connector 264H, the first and second combined electrical connectors 266-1 and 266-2 (for motor power output plus sensor signal wire connector(s), etc.), a plurality of feedthrough capacitors 295, communications circuitry 296A, first and second inverter circuitry 296B₁ and 296B₂, optional ferrites 297-1, 297-2, 297-3, and 297-4, LV EMI filter circuitry 298L, and HV EMI filter circuitry 298H.

As shown, the LV connector 264L is a single integrated input/output connector that includes low voltage power line connections (+/−), configured to operate at low voltages such as below 500 VDC, communications signal line connections such as an “enable” line, high and low communication lines (e.g., for Controller Area Network (CAN) high/low signals), and a plurality of HV interlock loop (HVIL) signal lines. The LV connector 264L can be connected to an external electrical cable (not shown) that can be electrically connected to a low voltage power supply and/or an external controller, such as the external ECU 65 (see FIG. 2). In this way, the LV connector 264L can accept both a LV power input to the electronics assembly 236 and also convey two-way low voltage electrical communication and/or sensor signals to and from the electronics assembly 236. There is also the “enable” signal (e.g., KL15), which can also be referred to as an “on” or “ignition” signal, that comes in through the LC connector 264L (keyed on power) which can engage the overall high voltage fan system 230. The enable signal can be sent by an external system such as the ECU 65.

In the illustrated embodiment, LV power input (+/−) electrical connections from the LV connector 264L are made to the LV EMI filter circuitry 298L and then to all of the inverter circuitry 296B₁ and 296B₂ as well as the communications circuitry 296A. In some embodiments, the communications circuitry 296A can be integrated on one or more circuit boards for the inverter circuitry 296B₁ and/or 296B₂, such that low voltage power is supplied to the communications circuitry 296A via circuit boards for the inverter circuitry 296B₁ and/or 296B₂. The enable signal line can be electrically connected to all of the inverter circuitry 296B₁ and 296B₂. CAN high/low signal lines are electrically connected to the communications circuitry 296A, which in turn is electrically connected to all of the inverter circuitry 296B₁ and 296B₂. The optional ferrites 297-1, 297-2, 297-3, and 297-4 can be arranged generally after electrical lines have left the LV connector 264L but before those electrical lines reach other electrically connected components such as the LV EMI filter circuitry 298L, the inverter circuitry 296B₁ and 296B₂, and the communications circuitry 296A. As shown in the illustrated embodiment, the ferrite 297-1 is used for the enable signal line and the LV+ power line, the ferrite 297-2 is used for the LV-power line, the ferrite 297-3 is used for all of the HVIL loop lines, and the ferrite 297-4 is used with the CAN high/low signal lines. In some embodiments, each ferrite 297-1 to 297-4 can comprise a pair of ferrite beads arranged at approximately 90° to each other, and can optionally have a wirewound configuration. The ferrites 297-1 to 297-4 help to reduce noise and interference within the interior volume V. However, use of the ferrites 297-1 to 297-4 is optional and they might be omitted, for instance, when many, most, or all of the electrical components in the interior volume V are provided on printed circuit boards, which tend to reduce ringing and have improved EMI and electromagnetic compatibility (EMC) performance over electrical connections made through individual wires. Other aspects of the ferrites 297-1 to 297-4 are discussed further later in the present disclosure.

The HV connector 264H of the illustrated embodiment includes high voltage power line connections (+/−), configured to operate at high voltages such as at 600 VDC or more (e.g., approximately 850 VDC or approximately 900 VDC), a plurality of HVIL loop signal lines, and a ground line. As shown the HV connector 264H is separate and distinct from the LV connector 264L. The HV connector 264H can be connected to an external electrical cable (not shown) that can be electrically connected to a high voltage power supply and/or an external controller, such as the external ECU 65 (see FIG. 2). In this way, the HV connector 264H can accept both a HV power input to the electronics assembly 236 and also provide HVIL safety functions. In general, HVIL loops function by allowing external systems, such as the ECU 65, to monitor for a break in the low voltage HVIL signal that can be used as a proxy to determine if an associated HV line is open or not and shut down associated HV power lines as a safety precaution where appropriate. Use of the HVIL loop helps protect people present near the system from potential electrical shocks during the assembly, repair, maintenance, and operation of the vehicle 51 and the high voltage electric cooling fan system 230. In the illustrated embodiment, HVIL loop signal lines are provided through both the HV connector 264H and the LV connector 264L as well as through both the combined electrical connectors 266-1 and 266-2, such that the HVIL loop comes in on the LV side and passes through all HV components. Grounding for the electronics assembly 236 can also be provided through the HV input connector 264H and an associated cable, which can ground at least the external wall of the enclosure 250 and, in turn, the electronics assembly 236 can provide grounding to the electric motor assemblies 234-1 and 234-2. Additionally, a safety ground 1000 can be provided that also electrically grounds the wall of the enclosure 250. The safety ground 1000 can provide a redundant ground path when the HV connector 264H is connected to ground (e.g., to a vehicle chassis) via an engaged wire or cable. In this way, grounding of the electronics assembly 236 and components grounded through it is not solely dependent on connection of a grounded cable to the HV connector 264H.

In the illustrated embodiment, HV power input (+/−) electrical connections from the HV connector 264H are made to the feedthrough capacitors 295, then to the HV EMI filter circuitry 298H, and then to all of the inverter circuitry 296B₁ and 296B₂.

The combined electrical connectors 266-1 and 266-1, as shown in the illustrated embodiment, each provide three-phase high voltage power output lines, sensor electrical signal lines, and HVIL loop signal lines. Each combined electrical connector 266-1 or 266-2 can be electrically connected to a corresponding one of the electric motor assemblies 234-1 or 234-2 with a cable 262-1 or 262-2. A ground line could optionally be provided between the electronics assembly 236 and the electric motor assemblies 234-1 and 234-2 through the cables 262-1 and 262-2 in some embodiments. The three-phase high voltage power output lines of a given combined electrical connector 266-1 or 266-1 are electrically connected to corresponding inverter circuitry 296B₁ or 296B₂, which can each generate high voltage three-phase power output. Moreover, the sensor lines of a given combined electrical connector 266-1 or 266-1 are electrically connected to corresponding inverter circuitry 296B₁ or 296B₂, which in turn can be electrically connected to the communications circuitry 296A. In general, each combined electrical connector 266-1 or 266-2 can thus be associated with given dedicated inverter circuitry 296B₁ or 296B₂ and a given electric motor assembly 234-1 or 234-2.

The communications circuitry 296A provides a module that allows the electronics assembly 236 of the high voltage electric cooling fan system 230 to receive instructions or requests from the ECU of the equipment being cooled by the system 230 (e.g., from an on-board vehicle computer such as ECU 65 of vehicle 51) such as rotational speed, rotational direction, and/or other signals that might be relevant, and to externally convey information about operational conditions of the high voltage electric cooling fan system 230. The most common communication protocol for vehicular applications is Controller Area Network (CAN). A typical CAN implementation suitable for use with the presently-disclosed system 230 is defined by the Society of Automotive Engineers (SAE) standard SAE J1939. In one embodiment, CAN signals originating externally are utilized to command general cooling requirements and govern the overall operation of the high voltage fan cooling system 230. The communications circuitry 296A in turn instructs the inverter circuitry 296B₁ and/or 296B₂, which, in some embodiments, involves converting CAN signals into suitable signals that govern operation of the inverter circuitry 296B₁ and/or 296B₂. The communications circuitry 296A can be integrated into one or more circuit board(s) for the inverter circuitry 296B₁ and/or 296B₂, or, alternatively, can be implemented as stand-alone circuitry, such as on a dedicated communications circuit board. In alternate embodiments, the communications circuitry 296A can be a Di+® controller available from Horton, Inc, (Roseville, MN, USA). As already noted, a low voltage communication cable can be electrically connected to the communications circuitry 296A that can be used for electrical communication signals (e.g., CAN signals, sensor signals, etc.) between the electronics assembly 236 and other external devices (e.g., an on-board vehicle computer such as ECU 65). Moreover, sensor signals from the electric motor assemblies 234-1 and/or 234-2 (e.g., a motor temperature signal) can be sent to the communications circuitry 296A, such as via the cables 262-1 or 262-2 and the inverter circuitry 296B₁ or 296B₂.

The inverter circuitry 296B₁ and 296B₂ (which can include one or more discrete inverter circuit boards or the like) provides power electronics circuitry modules that each contain high-speed electronic switching devices known as IGBTs or SiC MOSFETs. These devices are able to turn a constant direct current (DC) input voltage signal into a (pseudo-alternating current) pseudo-sinusoidal phased voltage output. Pulse-width modulation (PWM) commands can be used to switch power transistors of the inverter circuitry 296B₁ and 296B₂ to control on/off intervals to create pulse waves with different widths that are combined into a pseudo sine wave that outputs alternating current (AC) power with varying voltage and frequency. In doing so, three phases of pseudo-sinusoidal signals can be sent to the three windings of the stator 272 of the corresponding electric motor assembly 234-1 or 234-2 causing the stator windings to selectively be energized to generate magnetic fields that interact with the permanent magnets of the rotor 274 to induce rotation and produce torque to rotate the associated cooling fan 238-1 or 238-2. In presently-disclosed embodiments, the inverter circuitry 296B₁ and 296B₂ can operate at high voltages in the range of approximately 500-1200 Volts DC, such as approximately 600 VDC or more, approximately 850 VDC or more, or approximately 900 VDC or more.

FIG. 11B is a schematic illustration of electrical components of the electronics assembly 336-1. The same illustrated configuration could also be used for any or all of the electronics assemblies 36-1 to 36-n and 336-2 as well. Many of the components described with respect to FIG. 11B will function in the same or a similar manner as those described with respect to FIG. 11A. As shown in the illustrated embodiment of FIG. 11B, the electronics assembly 336-1 includes the enclosure 350 that includes a wall (e.g., an external-facing wall) and that defines the interior volume V, the low voltage (LV) connector 364L, the high voltage (HV) connector 364H, the first and second combined electrical connectors 366-1 and 366-2 (for motor power output plus sensor signal wire connector(s), etc.), a plurality of feedthrough capacitors 395, communications circuitry 396A, inverter circuitry 396B, optional ferrites 397-1, 397-2, 397-3, and 397-4, LV EMI filter circuitry 398L, and HV EMI filter circuitry 398H.

As shown, the LV connector 364L is a single integrated input/output connector that includes low voltage power line connections (+/−), configured to operate at low voltages such as below 500 VDC, communications signal line connections such as an “enable” line, high and low communication lines (e.g., for CAN high/low signals), and a plurality of HVIL loop signal lines. The LV connector 364L can be connected to an external electrical cable (not shown) that can be electrically connected to a low voltage power supply and/or an external controller, such as the external ECU 65 (see FIG. 2). In this way, the LV connector 264L can accept both a LV power input to the electronics assembly 236 and also convey two-way low voltage electrical communication and/or sensor signals to and from the electronics assembly 236. There is also the “enable” signal (e.g., KL15), which can also be referred to as an “on” or “ignition” signal, that comes in through the LC connector 264L (keyed on power) which can engage the overall high voltage electric cooling fan system 330. The enable signal can be sent by an external system such as the ECU 65.

In the illustrated embodiment, LV power input (+/−) electrical connections from the LV connector 364L are made to the LV EMI filter circuitry 398L and then to the inverter circuitry 396B as well as the communications circuitry 396A. In some embodiments, the communications circuitry 396A can be integrated on one or more circuit boards for the inverter circuitry 396B, such that low voltage power is supplied to the communications circuitry 396A via circuit boards for the inverter circuitry 396B. The enable signal line can be electrically connected to the inverter circuitry 396B. CAN high/low signal lines are electrically connected to the communications circuitry 396A, which in turn is electrically connected to the inverter circuitry 396B. The optional ferrites 397-1, 397-2, 397-3, and 397-4 can be arranged generally after electrical lines have left the LV connector 364L but before those electrical lines reach other electrically connected components such as the LV EMI filter circuitry 398L, the inverter circuitry 396B, and the communications circuitry 396A. As shown in the illustrated embodiment, the ferrite 397-1 is used for the enable signal line and the LV+ power line, the ferrite 397-2 is used for the LV-power line, the ferrite 397-3 is used for all of the HVIL loop lines, and the ferrite 397-4 is used with the CAN high/low signal lines. In some embodiments, each ferrite 397-1 to 397-4 can comprise a pair of ferrite beads arranged at approximately 90° to each other, and can optionally have a wirewound configuration. The use of the ferrites 397-1 to 397-4 is optional and they might be omitted, for instance, when many, most, or all of the electrical components in the interior volume V are provided on printed circuit boards. Other aspects of the ferrites 397-1 to 397-4 are discussed elsewhere in the present disclosure.

The HV connector 364H of the illustrated embodiment includes high voltage power line connections (+/−), configured to operate at high voltages such as at 600 VDC or more (e.g., approximately 850 VDC or approximately 900 VDC), a plurality of HVIL loop signal lines, and a ground line. As shown the HV connector 364H is separate and distinct from the LV connector 364L. The HV connector 364H can be connected to an external electrical cable (not shown) that can be electrically connected to a high voltage power supply and/or an external controller, such as the external ECU 65 (see FIG. 2). In this way, the HV connector 364H can accept both a HV power input to the electronics assembly 336-1 and also provide HVIL safety functions, as discussed elsewhere. In the illustrated embodiment, HVIL loop signal lines are provided through both the HV connector 364H and the LV connector 364L, as well as to the motor connection(s), such that the HVIL loop comes in on the LV side and passes through all HV components. Moreover, in the illustrated embodiment, HV power input (+/−) electrical connections from the HV connector 364H are made to the feedthrough capacitors 395, then to the HV EMI filter circuitry 398H, and then to the inverter circuitry 396B.

Grounding for the electronics assembly 336-1 can also be provided through the HV input connector 364H and an associated cable, which can ground at least the external wall of the enclosure 350 and, in turn, the electronics assembly 336-1 can optionally provide grounding to the electric motor assembly 334-1. Additionally, a safety ground 1000 can be provided that also electrically grounds the wall of the enclosure 350. The safety ground 1000 can provide a redundant ground path when the HV connector 364H is connected to ground (e.g., to a vehicle chassis) via an engaged wire or cable.

Three-phase high voltage power output lines, sensor electrical signal lines, and HVIL loop signal lines can pass out of the enclosure 350 of the electronics assembly 336-1 and to the associated electric motor assembly 334-1 through the wiring opening 399, in some embodiments. In embodiments in which the electronics assembly 336-1 and the electric motor assembly 334-1 are provided as a combined unit U₁, there is no need to have an external cable and instead simpler interior-grade wires or other similar electrical lines can be used when they are located inside a scaled boundary of the combined unit U₁. A ground line could optionally be provided between the electronics assembly 336-1 and the electric motor assembly 334-1 through the wiring opening 399 in some embodiments. The three-phase high voltage power output lines are electrically connected to the inverter circuitry 396B, which can generate high voltage three-phase power output. Moreover, the sensor lines can be electrically connected to the inverter circuitry 396B, which in turn can be electrically connected to the communications circuitry 396A. In general, the inverter circuitry 396B can be electrically connected to a dedicated electric motor assembly 334-1, such as part of the combined unit U₁. It should be understood that another combined unit U₂ can be provided with another inverter in another enclosure of another electronics assembly 336-2 to power and drive another electric motor assembly 334-2.

The communications circuitry 396A provides a module that allows the electronics assembly 336-1 of the high voltage cooling fan system 330 to receive instructions or requests from the ECU of the equipment being cooled by the system 330 (e.g., from an on-board vehicle computer such as ECU 65 of vehicle 51) such as rotational speed, rotational direction, and/or other signals that might be relevant, and to externally convey information about operational conditions of the high voltage electric cooling fan system 230. For example, SAE standard SAE J1939 can be utilized for CAN communications in one embodiment. In one embodiment, CAN signals originating externally are utilized to command general cooling requirements and govern the overall operation of the high voltage electric cooling fan system 330. The communications circuitry 396A in turn instructs the inverter circuitry 396B, which, in some embodiments, involves converting CAN signals into suitable signals that govern operation of the inverter circuitry 396B. The communications circuitry 396A can be integrated into one or more circuit board(s) for the inverter circuitry 396B, or, alternatively, can be implemented as stand-alone circuitry, such as on a dedicated communications circuit board. In alternate embodiments, the communications circuitry 396A can be a Di+® controller. As already noted, a low voltage cable can be electrically connected to the communications circuitry 396A that can be used for electrical communication signals (e.g., CAN signals, sensor signals, etc.) between the electronics assembly 336-1 and other external devices (e.g., an on-board vehicle computer such as ECU 65). Moreover, sensor signals from the electric motor assembly 334-1 (e.g., a motor temperature signal) can be sent to the communications circuitry 396A, such as via the inverter circuitry 396B. In the illustrated embodiment, the communications circuitry 396A may handle only communications associated with operation of the electric motor assembly 334-1, and not any other electric motor assemblies of the system 330.

The inverter circuitry 396B contains a power electronics circuitry module with high-speed electronic switching devices known as IGBTs or SiC MOSFETs, the operation of which was briefly described already. In general, the inverter can generate three phases of pseudo-sinusoidal signals that can be sent to the three windings of the stator 372 of the corresponding electric motor assembly 334-1 causing the stator windings to selectively be energized to generate magnetic fields that interact with the permanent magnets of the rotor 374 to induce rotation and produce torque to rotate the associated cooling fan 338-1. In presently-disclosed embodiments, the inverter circuitry 396B can operate at high voltages in the range of approximately 500-1200 Volts DC, such as approximately 600 VDC or more, approximately 850 VDC or more, or approximately 900 VDC or more.

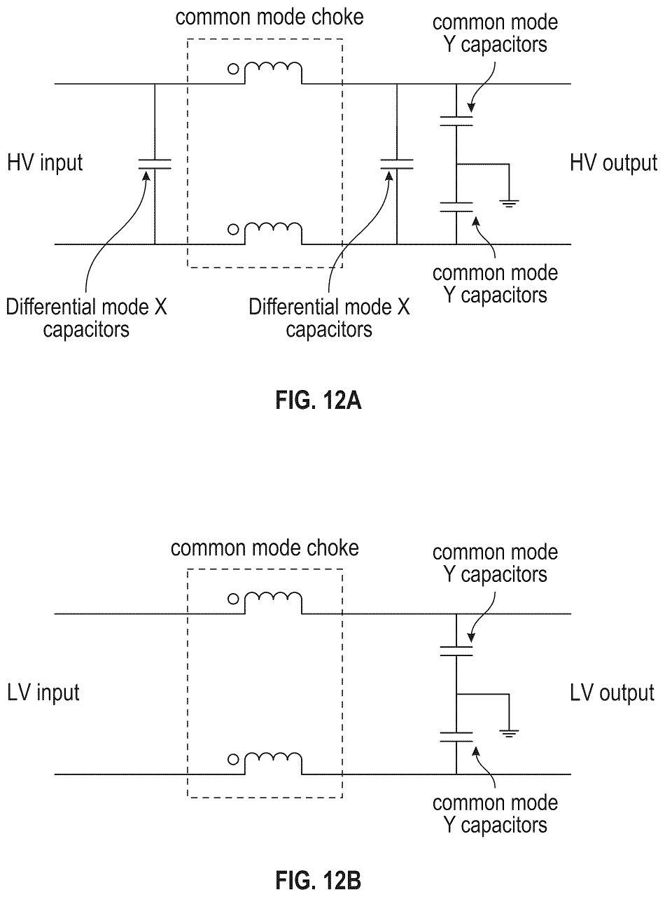

Example HV EMI filter circuitry suitable for use as the HV EMI filter circuitry 298H or 398H is shown schematically in FIG. 12A. The illustrated circuitry provides LV LC filtering functionality to help block or reduce noise in the form of EMI. This LC filtering can provide high, low, and/or band-pass filtering for HV power delivered to the inverter circuitry in the interior volume of a given electronics assembly enclosure. More particularly, in the embodiment illustrated in FIG. 12A, between a HV input and HV output, the HV EMI filter circuitry provides common mode choke coils (the inductors “L” of the LC filter) located in between differential mode X capacitors, and common mode Y capacitors with a ground connection between the last differential mode X capacitors and the HV output. The X & Y capacitors are the capacitors “C” of the LC filter. The HV input can be a HV power input, such as from an external power source and/or feedthrough capacitors. The HV output can be delivered to the inverter circuitry.

Example LV EMI filter circuitry suitable for use as the LV EMI filter circuitry 298L or 398L is shown schematically in FIG. 12B. The illustrated circuitry also provides LV LC filtering functionality to help block or reduce noise in the form of EMI. This LC filtering can provide high, low, and/or band-pass filtering for LV power delivered to communications circuitry in the interior volume of a given electronics assembly enclosure that is sealed against liquid incursion. Because the LV power is delivered in the same enclosure as the HV power, as previously explained, there is a heightened possibility of EMI and noise-related signal degradation. In the embodiment illustrated of FIG. 12B, between a LV input and LV output, the LV EMI filter circuitry provides common mode choke coils followed by common mode Y capacitors with a ground connection. In this respect, the LV EMI filter circuitry can omit the differential mode X capacitors present in the HV EMI filter circuitry, in some embodiments. The LV input can be a LV power input, such as from an external power source. The LV output can be delivered to the communications circuitry directly or indirectly (e.g., via a LV portion of the inverter circuitry).

The HV and LV EMI filter circuitry described with respect to FIGS. 12A and 12B can be implemented on one or more circuit boards. It has been discovered that use of a single circuit board for the EMI filter components (e.g., as shown in the embodiment of FIG. 7), as opposed to using discrete wired connections, not only saves packaging space but also reduces ringing effects to improve EMI and EMC performance. Moreover, use of a filter circuit board allows the filter circuit board(s) to be mounted to wall(s) of the electronics assembly enclosure with standoffs (e.g., standoffs 250S and 350S) that provide a relatively large surface area for grounding, where the enclosure wall and the standoffs 250S and 350S are grounded.

FIG. 13A is a perspective view of an embodiment of a ferrite assembly 1097 and FIG. 13B is a perspective view of a portion of a holder 1097H of the ferrite assembly shown in isolation. The holder 1097H can be a multi-piece assembly with a plurality of cavities 1097H-1 that can each accept a ferrite bead 1097A₁, 1097A₂, 1097B₁, 1097B₂, 1097C₁, or 1097C₂. The holder 1097H can be made of a model polymer material or other non-electrically-conductive material. Along one or more of the cavities 1097H-1 can be an opening 1097H-2 in which a biasing element 1097H-3 is arranged. The biasing element 1097H-3 can be, for example, a cantilevered beam with an optional distal end flange or hook and a living hinge at a proximal or connected end or alternatively a spring such as a leaf spring, coil spring, or compressible pad. In the illustrated embodiment the biasing element 1097H-3 is a cantilevered beam that extends into the opening 1097H02 and connected to the rest of the holder 1097H with a living hinge. The biasing element 1097H-3 can apply a biasing force to the ferrite bead 1097A₁, 1097A₂, 1097B₁, 1097B₂, 1097C₁, or 1097C₂ in the corresponding cavity 1097H-1, such as a transverse biasing force.

The ferrite beads 1097A₁, 1097A₂, 1097B₁, 1097B₂, 1097C₁, and 1097C₂ can be generally cylindrical. The holder 1097H can arrange the ferrite beads in pairs (1097A₁ and 1097A₂; 1097B₁ and 1097B₂; and 1097C₁ and 1097C₂) arranged at approximately 90° to each other. Electrical wires W can be wrapped through and around given pairs of the ferrite beads 1097A₁ and 1097A₂; 1097B₁ and 1097B₂; and/or 1097C₁ and 1097C₂ (and parts of the holder 1097H) in a wirewound configuration. For instance, a given set of the wires W can be wrapped in two to three passes, such as three times through and twice around a given pair of the ferrite beads 1097A₁ and 1097A₂; 1097B₁ and 1097B₂; or 1097C₁ and 1097C₂. Use of the ferrite beads 1097A₁, 1097A₂, 1097B₁, 1097B₂, 1097C₁, and/or 1097C₂ can help quiet electrical noise and EMI, particularly for LV circuitry.

In alternative embodiments, the ferrite assembly 1097 could instead be integrated into one or more circuit boards suing on-board ferrite beads or the like.

During operation of the high voltage electric cooling fan system 30, 130, 230, or 330, cooling demand signals from an external system such as the ECU 65 can be received by communications circuitry of a given electronics assembly and used to selectively power one or more associate electric motor assemblies to generate torque to rotate associated fan(s) to achieve desired cooling.

It is generally desirable to control the fan motor(s) to specific speeds, such as a speed setpoint. Increased fan speed will increase the amount of cooling air moved by the fan(s) (for instance, increasing the amount of cooling air that moves across or past a vehicle heat exchanger). But because fan power requirements increase at a cubic rate with speed, it is also desirable to maintain the lowest possible fan speed in order to keep fan power consumption to a relative minimum. Closed loop control can be employed in this situation to spin the fan(s) at a desired speed (or speeds). It is also preferable to keep the fan speed as constant as possible. If the fan speed is hunting or oscillating, it can make a noticeable and undesirable noise. Closed loop control requires the detection of the speed the fan motor is running at. The control electronics will essentially compare the actual speed to the desired speed and then adjust control gain parameters depending on factors such as the difference between actual and desired fan speed, the amount of time the difference is maintained, as well as the rate of change in the speed of the motor. This is commonly referred to as a Proportional, Integral, Derivative (PID) control system. Such control electronics can be provided by one of, or alternatively some combination of, the communications circuitry, the inverter circuitry, and/or an external ECU.

Speed measurement can be achieved without a speed sensor by, for example, measuring a voltage change in each of the motor's phase wires when they are not energized. There are three general states for each of the phase windings during operation. The first is a powered state causing attraction of the magnet on the rotor for propulsion. The second is a de-energizing state where the induced energy in the phase winding is dissipated. The collapse of the magnetic field during this second state causes a spike in voltage from the winding and some current that dissipates the built-up electromagnetic energy. This is known as back electromotive force (back EMF). The final state is where there is no voltage applied to the winding and the induced energy has been dissipated in the second state. During this final state, a change in voltage can be measured due to the movement of magnets on the rotor that are rotationally approaching or moving away from the winding. This is another form of back EMF that is derived from the magnets rotating within the winding of the stator, and is the same principle that is used to generate electricity. The speed of the rotor can be determined by counting the frequency at which this final-state phenomenon occurs. The speed determined by the frequency of the voltage changes in the non-energized windings can then be fed into the PID control loop and used to adjust the control parameters. The sensed fan motor speed can also be sent back through the communications system (and optionally to external systems) for other purposes, such as diagnostics. In further embodiments, other types of sensorless speed measurement techniques can be used, or a speed sensor could be utilized.

In light of the discussion above and the accompanying figures, persons of ordinary skill in the art will appreciate the present invention also includes methods of making and using a high voltage electric cooling fan system, and components thereof. Of note is that electric motor assemblies according to embodiments of the present invention can allow for fabrication using a generally axial stack-up assembly procedure. That is, many of the components can be installed and secured together generally along or substantially parallel to an axis of rotation of the electric motor. This can help simplify assembly. Furthermore, many of the components of embodiments of the high voltage cooling fan system can have a modular, or semi-modular configuration. This allows different components to be utilized in multiple different overall system configurations. For example, the housing body (or base), stator, and rotor of embodiments of the electric motor assembly can be utilized with both remotely located electronics assembly configurations as well as embodiments with a combined unit incorporating both an electronics assembly and an electric motor assembly. Various assemblies are also usable with different numbers of fans, that is, the number of fans and associated motor and electronics assemblies can be scaled up and multiplied as desired for particular applications.

### Discussion of Possible Embodiments

An electric cooling fan system can include: a frame; a first fan; a first electric motor assembly supported by the frame and operably connected to the first fan; a second fan; a second electric motor assembly supported by the frame and operably connected to the second fan; and a liquid cooling path that passes adjacent to both a first stator of the first electric motor assembly and a second stator of the second electric motor assembly such that thermal energy is transferable from the first electric motor assembly and the second electric motor assembly to a liquid coolant present in the liquid cooling path.

The electric cooling fan system of the preceding paragraph can optionally include, additionally and/or alternatively, any one or more of the following features, configurations and/or additional components:
a hose defining a portion of the liquid cooling path;
the hose can include a curved portion in which material of the hose is hardened to maintain a curved shape of the curved portion;
the liquid cooling path can be configured to pass the first electric motor assembly followed by the second electric motor assembly in flow series;
a liquid coolant inlet line fluidically connected to a first channel located adjacent to the stator of the first electric motor assembly; a liquid coolant series connection line fluidically connected between the first channel and a second channel located adjacent to the stator of the second electric motor assembly; and a liquid coolant outlet line fluidically connected to the second channel;
the first channel can turn the liquid coolant passing through the first electric motor assembly over an angle of at least approximately 180°;
the liquid cooling path can include first and second branches that pass the first electric motor assembly and the second electric motor assembly in parallel;
a liquid coolant inlet manifold in the liquid cooling path, with the liquid coolant inlet manifold fluidically connected to both a first channel located adjacent to the stator of the first electric motor assembly in the first branch of the liquid cooling path and a second channel located adjacent to the stator of the second electric motor assembly in the second branch of the liquid cooling path; and a liquid coolant outlet manifold in the liquid cooling path, with the liquid coolant outlet manifold fluidically connected to both the first channel and the second channel;
the liquid coolant inlet manifold and the liquid coolant outlet manifold can both be located adjacent to the frame and are both positioned in a region located in between respective axes of rotation of the first electric motor assembly and the second electric motor assembly;
an electronics assembly spaced from the frame that includes electronic circuitry and an electronics cooling channel located adjacent to the electronic circuitry, with the electronics cooling channel being fluidically connected to the liquid cooling path;
the electronic circuitry of the electronics assembly can include inverter circuitry on one or more circuit boards that powers the first electric motor assembly and the second electric motor assembly;
the first electric motor assembly and the second electric motor assembly can each be configured to be powered by an electric current at greater than or equal to 850 Volts DC;
the liquid cooling path can pass through a first channel in a first housing cover of the first electric motor assembly, with the first channel positioned axially adjacent to the first stator and a first rotor of the first electric motor assembly;
the first housing cover can include a wire cavity, and the first channel can pass around at least a portion of a perimeter of the wire cavity without intersecting the wire cavity;
a first electronics assembly electrically connected to the first electric motor assembly and having a first electronics enclosure that contains power electronics circuitry;
the first electric motor assembly can include a first housing,
the first electronics enclosure can be connected to the first housing and can cover an opening in the first housing;
bearings can rotatably support a first rotor of the first electric motor assembly on the first electronics enclosure;
the first electronics enclosure can include a first electronics cooling channel fluidically connected to the liquid cooling path, at least a portion of the first electronics cooling channel can be positioned in between a first stator of the first electric motor assembly and the power electronics circuitry contained in the first electronics enclosure such that thermal energy is transferable from both the first electric motor assembly and the power electronics circuitry contained in the first electronics enclosure to the liquid coolant present in the first electronics cooling channel;
a second electronics assembly electrically connected to the second electric motor assembly and having a second electronics enclosure that contains power electronics circuitry and that further includes a second electronics cooling channel fluidically connected to the liquid cooling path, the second electric motor assembly can include a second housing;
the second electronics enclosure can be connected to the second housing, at least a portion of the second electronics cooling channel can be positioned in between a second stator of the second electric motor assembly and the power electronics circuitry contained in the second electronics enclosure such that thermal energy is transferable from both the second electric motor assembly and the power electronics circuitry contained in the second electronics enclosure to the liquid coolant present in the second electronics cooling channel;
the frame can include a pair of crossbars spaced from each other and a plurality of legs connected to the crossbars, the first electric motor assembly and the second electric motor assembly can both be attached to the crossbars, and at least one of the plurality of legs can include a tube having a nonlinear shape;
all tubular portions of the frame can closed against liquid incursion;
the at least one of the plurality of legs that comprises the tube further comprises a solid end portion connected to the tube, an interface between the tube and the solid end portion can be closed against liquid incursion, and a fastener opening can pass through the solid end portion;
the first fan and the second fan can be arranged side by side with parallel axes of rotation;
respective first and second housings of the first electric motor assembly and the second electric motor assembly can be positioned at least partially in between the crossbars of the frame;
the first fan can include a cup-shaped hub and a plurality of blades, the cup-shaped hub can be rotationally fixed to a first rotor shaft of the first electric motor assembly, and leading edges of the plurality of blades can be located no further axially forward than a front end of the first rotor shaft; and/or a circulating pump fluidically connected to the liquid cooling path.

A liquid-cooled electric fan system can include: an electric motor including a rotor with a rotor shaft, a stator, and a motor housing, the rotor can be positioned adjacent to the stator, and the motor housing can at least partially surround the rotor and the stator; a fan operably connected to the rotor shaft such that a torque output from the electric motor can rotate the fan; an electronics enclosure attached to the motor housing, the electronics enclosure including inverter circuitry electrically connected to the electric motor; and a liquid cooling channel positioned between the inverter circuitry and the stator, the liquid cooling channel can contain a liquid coolant capable of accepting thermal energy from one or both of the electric motor and the inverter circuitry.

The liquid-cooled electric fan system of the preceding paragraph can optionally include, additionally and/or alternatively, any one or more of the following features, configurations and/or additional components:
the motor housing can have an opening, and the electronics enclosure can cover the opening of the motor housing;
a rear end of the rotor shaft can be rotatably supported on the electronics enclosure by bearings, and a front end of the rotor shaft can be rotatably supported on the motor housing by additional bearings;
a seal engaged between the motor housing and the electronics enclosure;
one or more additional liquid cooling channels, with the liquid cooling channel and the one or more additional liquid cooling channels fluidically connected in parallel;
a wiring opening in the electronics enclosure arranged to face the electric motor, the liquid cooling channel and the one or more additional liquid cooling channels do not intersect the wiring opening, and a seal engaged between the motor housing and the electronics enclosure outward from the wiring opening;
the liquid cooling channel can be located in a wall of the electronics enclosure;
the electronics enclosure and the motor housing, when attached together, can be sealed against liquid incursion;
a thermal paste can be positioned in between the inverter circuitry and the liquid cooling channel; and/or
the inverter circuitry can comprise multiple inverter circuit boards.

An electric cooling fan system can include: a frame that includes a pair of crossbars spaced from each other in a substantially parallel arrangement and a plurality of legs each connected to both of the crossbars, at least one of the plurality of legs can comprise a tube having a nonlinear shape, and all tubular portions of the frame can be closed against liquid incursion; a first electric motor attached to both of the crossbars; and a first fan operably connected to the first electric motor.

The electric cooling fan system of the preceding paragraph can optionally include, additionally and/or alternatively, any one or more of the following features, configurations and/or additional components:
the at least one of the plurality of legs that comprises the tube can further comprise a solid end portion connected to the tube, an interface between the tube and the solid end portion can be closed against liquid incursion, and a fastener opening can pass through the solid end portion;
a lifting eyelet extending from one of the plurality of legs;
a second fan; a second electric motor attached to both of the crossbars and operably connected to the second fan; and/or
the first fan and the second fan can be arranged side by side with substantially parallel axes of rotation, and the first electric motor and the second electric motor can be positioned at least partially in between the crossbars of the frame.

An electric fan system can include: an electric motor including a rotor, a stator, and a motor housing, with the rotor positioned adjacent to the stator, and with the motor housing at least partially surrounding the rotor and the stator; a fan operably connected to the electric motor such that a torque output from the electric motor can rotate the fan; and an electronics assembly. The electronics assembly can include: a base; a cover attached to the base, such that the base and the cover enclose an interior volume, with the electric fan system (as a whole) configured such that the interior volume is sealed against liquid incursion; a high voltage electrical connector that passes through either the base or the cover; a low voltage electrical connector that passes through either the base or the cover; inverter circuitry located in the interior volume and electrically connected to both the electric motor and the high voltage electrical connector, with the inverter circuitry being configured to generate a power output at greater than or equal to 850 Volts DC; and communications circuitry located in the interior volume and electrically connected to both the inverter circuitry and the low voltage electrical connector, with the communications circuitry being configured to operate at less than 500 Volts DC.

The electric fan system of the preceding paragraph can optionally include, additionally and/or alternatively, any one or more of the following features, configurations and/or additional components:
an electronics liquid cooling channel that passes through the base, and which can contain a liquid coolant capable of accepting thermal energy from the inverter circuitry;
the motor housing can include a motor liquid cooling channel, with the motor liquid cooling channel and the electronics liquid cooling channel connected in fluid communication by a liquid cooling path;
a thermal paste can be positioned between the inverter circuitry and the base;
at least a wall of the base can be made of a metallic material and can be electrically grounded;
electrical grounding to the wall can be provided through an electrical cable connected to the high voltage electrical connector;
the electric motor can have a three-phase brushless DC motor configuration;
the high voltage electrical connector can be configured as a high voltage input connector, and the electronics assembly can be located remotely from the electric motor;
a combined electrical connector electrically connected to both the inverter circuitry and the communications circuitry, with the combined electrical connector configured to transmit high voltage power output from the inverter circuitry to the electric motor as well as lower voltage sensor signals between the communications circuitry and a sensor of the electric motor;
an additional electric motor electrically connected to the inverter circuitry, an additional fan operably connected to the additional electric motor, and an additional combined electrical connector electrically connected to both the inverter circuitry and the communications circuitry;
the low voltage electrical connector can pass through the cover, and both the high voltage electrical connector and the combined electrical connector can pass through the base;
the inverter circuitry can comprise a plurality of discrete inverter circuit boards;
high voltage LC filter circuitry electrically connected to the inverter circuitry, and low voltage LC filter circuitry electrically connected to the communications circuitry;
standoffs, with a filter circuit board mounted to the base via the standoffs such that the filter circuit board is arranged in a stacked and substantially physically parallel relationship to at least one inverter circuit board that comprises either or both of the high voltage LC filter circuitry and/or the low voltage LC filter circuitry;
a plurality of ferrite beads, with wiring electrically connected to the communications circuitry passing through a first pair of the plurality of ferrite beads oriented at 90° to each other in a wirewound configuration; and/or
a holder that secures the plurality of ferrite beads, wherein the holder is made of a polymer material and includes a biasing element with a living hinge that applies a transverse force to one of the plurality of ferrite beads.

An electronics assembly can include: an enclosure having an interior volume, which can be liquid-tight; inverter circuitry located within the interior volume, with at least a portion of the inverter circuitry configured to operate at high voltages greater than 600 VDC; communications circuitry located within the interior volume, with the communications circuitry configured to operate at low voltages less than 500 VDC; high voltage electromagnetic interference (EMI) filter circuitry located within the interior volume and electrically connected between a high voltage power input and the inverter circuitry, the high voltage EMI filter circuitry including at least one common mode choke inductor coil, at least one differential mode X capacitor, and at least one common mode Y capacitor; and low voltage EMI filter circuitry located within the interior volume and electrically connected between a low voltage power input and the communications circuitry, the low voltage EMI filter circuitry including at least one common mode choke inductor coil and at least one common mode Y capacitor, with the low voltage EMI filter circuitry having a different configuration than the high voltage EMI filter circuitry.

The electronics assembly of the preceding paragraph can optionally include, additionally and/or alternatively, any one or more of the following features, configurations and/or additional components:
a plurality of feedthrough capacitors electrically connected in between the high voltage power input and the high voltage EMI filter circuitry;
the high voltage EMI filter circuitry and the low voltage EMI filter circuitry can both be provided on a single first circuit board;
the enclosure can be made of a metallic material, and the first circuit board can be electrically grounded to the enclosure;
the inverter circuitry and the communications circuitry can both be provided on a second circuit board, and the first circuit board and the second circuit board can be arranged in a stacked configuration inside the interior volume in a substantially parallel relationship;
a plurality of standoffs at least one of which is electrically grounded, with the first circuit board secured to the plurality of standoffs and electrically grounded to the at least one electrically grounded standoff;
a liquid cooling channel can extend through a first wall of the enclosure, separate from the interior volume, and the second circuit board can be located adjacent to the liquid cooling channel and the first wall;
the second circuit board can be located in between the first wall and the first circuit board;
a pair of ferrite beads oriented at approximately 90° to each other, with wiring electrically connected to the communications circuitry passing through the pair of ferrite beads in a wirewound configuration; and/or
the inverter circuitry is configured to provide a high voltage power output at greater than or equal to 850 VDC.

A method of making an electric cooling fan system can include: bending metallic tubes to form a plurality of legs having nonlinear shapes; securing a pair of crossbars spaced from each other in a substantially parallel arrangement to each of the plurality of legs; after the pair of crossbars are secured to the plurality of legs, welding end pieces to open ends of the plurality of legs to create a frame, such that all tubular portions of the frame are closed against liquid incursion, wherein each of the end pieces has a fastener opening to accept a mechanical fastener suitable to mount the frame at a mounting location; attaching a first electric motor assembly to each of the crossbars after the frame is created; and operably connecting a first fan to the first electric motor assembly.

The method of the preceding paragraph can optionally include, additionally and/or alternatively, any one or more of the following features, configurations and/or additional steps:
fluidically connecting hoses to a liquid cooling channel of the first electric motor assembly to a liquid cooling path that extends to a heat exchanger;
attaching a second electric motor assembly to each of the crossbars after the frame is created, with the second electric motor assembly located adjacent to the first electric motor assembly, and fluidically connecting hoses to a liquid cooling channel of the second electric motor assembly to the liquid cooling path that extends to the heat exchanger;
the hoses can fluidically connect the liquid cooling channels of the first and second electric motor assemblies to the liquid cooling path in flow series;
fluidically connecting an inlet manifold and an outlet manifold to the hoses, such that the liquid cooling channels of the first and second electric motor assemblies are fluidically connected to the liquid cooling path in parallel; and/or securing a lifting eyelet to one of the plurality of legs.

### Summation

Any relative terms or terms of degree used herein, such as “substantially”, “essentially”, “generally”, “approximately” and the like, should be interpreted in accordance with and subject to any applicable definitions or limits expressly stated herein. In all instances, any relative terms or terms of degree used herein should be interpreted to broadly encompass any relevant disclosed embodiments as well as such ranges or variations as would be understood by a person of ordinary skill in the art in view of the entirety of the present disclosure, such as to encompass ordinary manufacturing tolerance variations, incidental alignment variations, transient alignment or shape variations induced by thermal, rotational or vibrational operational conditions, transitory signal fluctuations, and the like. Moreover, any relative terms or terms of degree used herein should be interpreted to encompass a range that expressly includes the designated quality, characteristic, parameter, or value, without variation, as if no qualifying relative term or term of degree were utilized in the given disclosure or recitation.

The word “comprise”, or variations such as “comprises” or “comprising” are used in an open-ended manner herein and should be interpreted to refer to the inclusion of a stated element, feature, or step, or group of elements, features, or steps, but not the exclusion of any other element, feature, or step, or group of elements, features, or steps. Unless further expressly qualified, use of the word “comprise” or variations thereof does not, alone, exclude the present additional, unrecited elements, steps, or groups of elements or steps. Additionally, unless further expressly qualified, the words “a” and “an” as used herein refer to one or more and do not limit the identified element, feature, step, or the like to one and only one. However, use of the words “a” and “an” herein should be interpreted in accordance with and subject to any applicable further limits expressly stated in the context of any particular instance of usage, without extending such context-specific limits to all other uses generally.

Although the present invention has been described with reference to preferred embodiments, workers skilled in the art will recognize that changes may be made in form and detail without departing from the spirit and scope of the invention. For example, features described or shown with respect to one embodiment can generally be utilized with other disclosed embodiments. Components such as liquid coolant hoses, electrical cables, connectors, ports, supports, and the like can be repositioned in different locations as desired for particular applications. Moreover, certain disclosed features and structures are optional and can be omitted in alternative embodiments. Lastly, persons of ordinary skill in the art will recognize that additional components, features, and steps that are not specifically discussed or illustrated can be utilized with the present invention as desired for particular applications.

1-36. (canceled)

37. An electric fan system comprising:
an electric motor including a rotor, a stator, and a motor housing, wherein the rotor is positioned adjacent to the stator, and wherein the motor housing at least partially surrounds the rotor and the stator;
a fan operably connected to the electric motor such that a torque output from the electric motor can rotate the fan; and
an electronics assembly including:
a base;
a cover attached to the base, wherein the base and the cover enclose an interior volume, and wherein the electric fan system is configured such that the interior volume is sealed against liquid incursion;
a high voltage electrical connector that passes through either the base or the cover;
a low voltage electrical connector that passes through either the base or the cover;
inverter circuitry located in the interior volume and electrically connected to both the electric motor and the high voltage electrical connector, wherein the inverter circuitry is configured to generate a power output at greater than or equal to 850 Volts DC; and
communications circuitry located in the interior volume and electrically connected to both the inverter circuitry and the low voltage electrical connector, wherein the communications circuitry is configured to operate at less than 500 Volts DC.

38. The electric fan system of claim 37 and further comprising:
an electronics liquid cooling channel that passes through the base, wherein the electronics liquid cooling channel contains a liquid coolant capable of accepting thermal energy from the inverter circuitry.

39. The electric fan system of claim 38, wherein the motor housing includes a motor liquid cooling channel, wherein the motor liquid cooling channel and the electronics liquid cooling channel are connected in fluid communication by a liquid cooling path.

40. The electric fan system of claim 37, wherein a thermal paste is positioned between the inverter circuitry and the base.

41. The electric fan system of claim 37, wherein at least a wall of the base is made of a metallic material and is electrically grounded.

42. The electric fan system of claim 41, wherein electrical grounding to the wall is provided through an electrical cable connected to the high voltage electrical connector.

43. The electric fan system of claim 37, wherein the electric motor has a three-phase brushless DC motor configuration.

44. The electric fan system of claim 37, wherein the high voltage electrical connector is configured as a high voltage input connector, and wherein the electronics assembly is located remotely from the electric motor, the electric fan system further comprising:
a combined electrical connector electrically connected to both the inverter circuitry and the communications circuitry, wherein the combined electrical connector is configured to transmit high voltage power output from the inverter circuitry to the electric motor as well as lower voltage sensor signals between the communications circuitry and a sensor of the electric motor.

45. The electric fan system of claim 44 and further comprising:
an additional electric motor electrically connected to the inverter circuitry;
an additional fan operably connected to the additional electric motor; and
an additional combined electrical connector electrically connected to both the inverter circuitry and the communications circuitry.

46. The electric fan system of claim 44, wherein the low voltage electrical connector passes through the cover, and wherein both the high voltage electrical connector and the combined electrical connector pass through the base.

47. The electric fan system of claim 37, wherein the inverter circuitry comprises a plurality of discrete inverter circuit boards.

48. The electric fan system of claim 37 and further comprising:
high voltage LC filter circuitry electrically connected to the inverter circuitry; and
low voltage LC filter circuitry electrically connected to the communications circuitry.

49. The electric fan system of claim 48 and further comprising:
standoffs, wherein a filter circuit board is mounted to the base via the standoffs such that the filter circuit board is arranged in a stacked and substantially physically parallel relationship to at least one inverter circuit board that comprises either or both of the high voltage LC filter circuitry and/or the low voltage LC filter circuitry.

50. The electric fan system of claim 37 and further comprising:
a plurality of ferrite beads, wherein wiring electrically connected to the communications circuitry passes through a first pair of the plurality of ferrite beads oriented at 90° to each other in a wirewound configuration.

51. The electric fan system of claim 50 and further comprising:
a holder that secures the plurality of ferrite beads, wherein the holder is made of a polymer material and includes a biasing element with a living hinge that applies a transverse force to one of the plurality of ferrite beads.

52. An electronics assembly comprising:
an enclosure having an interior volume, wherein the enclosure is liquid-tight;
inverter circuitry located within the interior volume, wherein at least a portion of the inverter circuitry is configured to operate at high voltages greater than 600 VDC;
communications circuitry located within the interior volume, wherein the communications circuitry is configured to operate at low voltages less than 500 VDC;
high voltage electromagnetic interference (EMI) filter circuitry located within the interior volume and electrically connected between a high voltage power input and the inverter circuitry, wherein the high voltage EMI filter circuitry includes at least one common mode choke inductor coil, at least one differential mode X capacitor, and at least one common mode Y capacitor; and
low voltage EMI filter circuitry located within the interior volume and electrically connected between a low voltage power input and the communications circuitry, wherein the low voltage EMI filter circuitry includes at least one common mode choke inductor coil and at least one common mode Y capacitor, and wherein the low voltage EMI filter circuitry has a different configuration than the high voltage EMI filter circuitry.

53. The electronics assembly of claim 52 and further comprising:
a plurality of feedthrough capacitors electrically connected in between the high voltage power input and the high voltage EMI filter circuitry.

54. The electronics assembly of claim 52, wherein the high voltage EMI filter circuitry and the low voltage EMI filter circuitry are both provided on a single first circuit board.

55. The electronics assembly of claim 54, wherein the enclosure is made of a metallic material, and wherein the first circuit board is electrically grounded to the enclosure.

56. The electronics assembly of claim 54, wherein the inverter circuitry and the communications circuitry are both provided on a second circuit board, and wherein the first circuit board and the second circuit board are arranged in a stacked configuration inside the interior volume in a substantially parallel relationship.

57. The electronics assembly of claim 56 and further comprising:
a plurality of standoffs at least one of which is electrically grounded, wherein the first circuit board is secured to the plurality of standoffs and electrically grounded to the at least one electrically grounded standoff.

58. The electronics assembly of claim 56 and further comprising:
a liquid cooling channel extending through a first wall of the enclosure, separate from the interior volume, wherein the second circuit board is located adjacent to the liquid cooling channel and the first wall.

59. The electronics assembly of claim 58, wherein the second circuit board is located in between the first wall and the first circuit board.

60. The electronics assembly of claim 52 and further comprising:
a pair of ferrite beads oriented at approximately 90° to each other, wherein wiring electrically connected to the communications circuitry passes through the pair of ferrite beads in a wirewound configuration.

61. The electronics assembly of claim 52, wherein the inverter circuitry is configured to provide a high voltage power output at greater than or equal to 850 VDC.

62-67. (canceled)
